(19) United States
(12) Patent Application Publication
(10) Pub. No.: US 2024/0407250 A1
(43) Pub. Date: Dec. 5, 2024

(54) COMPOSITION FOR ORGANIC ELECTROLUMINESCENT ELEMENT, METHOD FOR PRODUCING ORGANIC ELECTROLUMINESCENT ELEMENT, ORGANIC ELECTROLUMINESCENT ELEMENT, DISPLAY DEVICE, AND ILLUMINATOR

(71) Applicant: Mitsubishi Chemical Corporation, Tokyo (JP)

(72) Inventors: Manabu SAKURAI, Tokyo (JP); Yuki OHSHIMA, Tokyo (JP); Koichiro IIDA, Tokyo (JP)

(73) Assignee: Mitsubishi Chemical Corporation, Tokyo (JP)

(21) Appl. No.: 18/798,043

(22) Filed: Aug. 8, 2024

Related U.S. Application Data
(63) Continuation of application No. PCT/JP2023/001496, filed on Jan. 19, 2023.

(30) Foreign Application Priority Data
Feb. 9, 2022 (JP) 2022-019088
Feb. 9, 2022 (JP) 2022-019089

(51) Int. Cl. H10K 85/30; H10K 71/15; H10K 85/60

(52) U.S. Cl. CPC H10K 85/342; H10K 71/15; H10K 85/654; H10K 85/6572

(57) ABSTRACT

An object of the present invention is to provide a composition for an organic electroluminescent element, which is used for forming an emission layer in an organic electroluminescent element by wet-process film formation, and which has favorable stability of liquid physical properties, in particular, favorable surface tension stability of ink. The present invention relates to a composition for an organic electroluminescent element including a functional material, a specific compound, alkylated naphthalene or diphenyl alkane as a first solvent, and at least one of an aromatic ether and an aromatic ester as a second solvent.

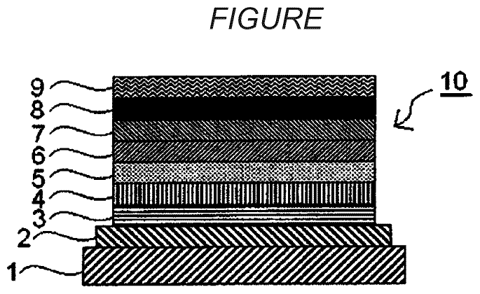

### CROSS-REFERENCE TO RELATED APPLICATIONS

This application is a continuation of International Application No. PCT/JP2023/001496, filed on Jan. 19, 2023, and claims the benefit of priority to Japanese Application No. 2022-019088 filed on Feb. 9, 2022 and Japanese Application No. 2022-019089 filed on Feb. 9, 2022. The content of each of these applications is hereby incorporated by reference in its entirety.

### TECHNICAL FIELD

The present invention relates to a composition for an organic electroluminescent element useful for forming an emission layer of an organic electroluminescent element (hereinafter, may be referred to as an “organic EL element”). The present invention also relates to an organic electroluminescent element having an emission layer formed using the composition for an organic electroluminescent element, a method for producing the same, and a display device and an illuminator having the organic electroluminescent element.

### BACKGROUND ART

Various electronic devices using an organic EL element, such as an organic EL illumination and an organic EL display, have been put to practical use. An organic electroluminescent element has small power consumption for its low applied voltage, and are capable of emitting light of three primary colors, and thus have started to be applied not only to large-sized display monitors but also to medium-to-small sized displays represented by mobile phones and smartphones.

The organic electroluminescent element is produced by laminating a plurality of layers such as an emission layer, a charge injection layer, and a charge transport layer. Currently, most of the organic electroluminescent elements are produced by depositing an organic material under vacuum, but a vacuum deposition method has a complicated deposition process and is inferior in productivity. In addition, in an organic electroluminescent element produced by the vacuum deposition method, it is extremely difficult to increase an area of a panel of illumination or display.

In recent years, as a process for efficiently producing an organic electroluminescent element that can be used for a large-sized display or illumination, a wet-process film formation method (coating method) has been studied. The wet-process film formation method has an advantage of being able to easily form a stable layer as compared with the vacuum deposition method, and thus is expected to be applied to mass production of displays and illuminators and large-sized devices.

In order to produce an organic electroluminescent element by the wet-process film formation method, it is necessary to use ink obtained by dissolving a functional material in an organic solvent. When solubility of the functional material in the organic solvent is low, the material may be deteriorated before use because an operation such as heating for a long period of time is required. Further, when a uniform state cannot be maintained for a long period of time in a solution state, precipitation of the material from the solution occurs, and film formation by an inkjet device or the like becomes impossible. The organic solvent used in the ink is required to have solubility in two ways of rapidly dissolving the functional material, and maintaining a uniform state without precipitating the functional material after the dissolution.

In recent years, attempts have been made to improve performance of an organic electroluminescent element by using, as an organic solvent used for ink for forming an emission layer by a wet-process film formation method, alkylated naphthalene or diphenyl alkane which has a high ability to dissolve a functional material, is difficult to volatilize under normal temperature and normal pressure, and applicable to large-area coating to increase emission efficiency of the organic electroluminescent element or lower a driving voltage (for example, Patent Literatures 1 to 4).

Even in a case where the organic electroluminescent element is produced after the ink is stored for a long period of time, an attempt to contain a phenol derivative in the ink has been made for the purpose of preventing a decrease in emission efficiency and driving lifetime of the organic electroluminescent element (for example, Patent Literatures 5 and 6).

Meanwhile, for the purpose of improving flatness of a film when a functional layer is formed by a wet-process film formation method, it is disclosed that an aromatic ether or an aromatic ester is mixed and used as an organic solvent used in ink (for example, Patent Literature 7).

### CITATION LIST

### Patent Literature

Patent Literature 1: WO2019-212022
Patent Literature 2: JP2016-108374A
Patent Literature 3: JP2014-102878A
Patent Literature 4: JP2018-046002A
Patent Literature 5: JP2015-63662A
Patent Literature 6: JP2015-93938A
Patent Literature 7: WO2019-017489

### SUMMARY OF INVENTION

### Technical Problem

According to the above-described prior art, by using a solvent that is difficult to volatilize under normal temperature and normal pressure such as alkylated naphthalene or diphenyl alkane, volatilization of the solvent can be controlled even when the solvent is applied to a large area by reducing a pressure after application, and by containing a phenol derivative in ink, deterioration of the functional material which is a cause of a decrease in the emission efficiency or the driving lifetime can be prevented even when the ink is stored for a long period of time. However, it is not sufficient from the viewpoint of stability of liquid physical properties of the ink, in particular, surface tension stability of the ink, and improvement of the stability of the liquid physical properties has been required.

An object of the present invention is to provide a composition for an organic electroluminescent element, which is used for forming an emission layer in an organic electroluminescent element by wet-process film formation, and which has favorable stability of liquid physical properties, in particular, favorable surface tension stability of ink.

### Solution to Problem

As a result of intensive studies, the present inventors have found that by using alkylated naphthalene or diphenyl alkane as a solvent, and further adding at least one of an aromatic ether and an aromatic ester (hereinafter, may be referred to as “aromatic ether and/or aromatic ester”) as a solvent in ink containing a phenol derivative and having a large change in liquid physical properties, a change in liquid physical properties becomes small even when the ink is stored for a long period of time, and the present inventors have completed the present invention.

That is, the gist of the present invention is as follows.

<1>

A composition for an organic electroluminescent element, containing:
a functional material,
a compound represented by the following formula (1),
alkylated naphthalene or diphenyl alkane as a first solvent, and
at least one of an aromatic ether and an aromatic ester as a second solvent,

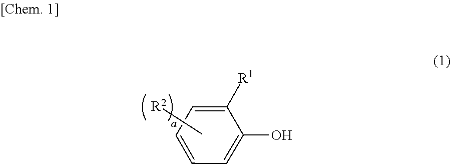

[in the above formula,
a is an integer of 0 to 4;
R¹ and R² each independently represent an alkyl group having 1 to 12 carbons or an alkoxy group having 1 to 12 carbons; and
in a case where a plurality of R² are present, the plurality of R² may be the same as or different from each other.]

<2>

The composition for an organic electroluminescent element according to <1>, in which
the diphenyl alkane is represented by the following formula (4B):

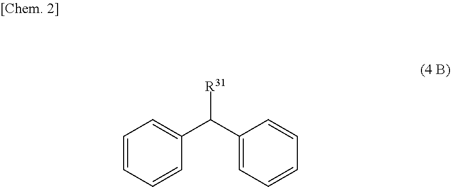

[in the above formula, R³¹ represents a hydrogen atom or an alkyl group.]

<3>

The composition for an organic electroluminescent element according to <1> or <2>, in which
the compound represented by the formula (1) is a compound represented by the following formula (1-1):

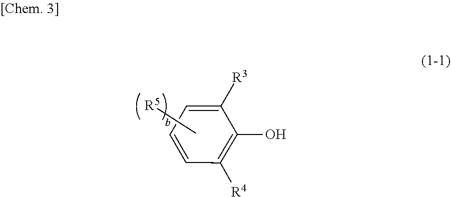

[in the above formula,
b is an integer of 0 to 3;
R³, R⁴, and R⁵ each independently represent an alkyl group having 1 to 12 carbons or an alkoxy group having 1 to 12 carbons; and
in a case where a plurality of R⁵ are present, the plurality of R⁵ may be the same as or different from each other.]

<4>

The composition for an organic electroluminescent element according to <3>, in which
the compound represented by the formula (1-1) is a compound represented by the following formula (1-2):

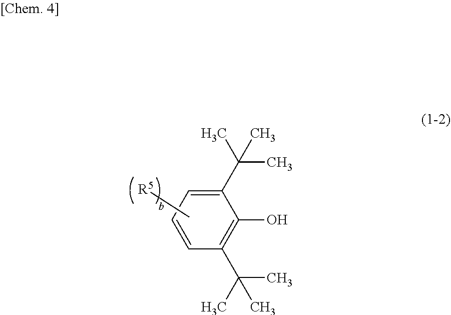

[in the above formula, b and R⁵ have the same meaning as b and R⁵ in the formula (1-1).]

<5>

The composition for an organic electroluminescent element according to any of <1> to <4>, in which
the functional material includes an iridium complex.

<6>

The composition for an organic electroluminescent element according to <5>, in which
the iridium complex is represented by the following formula (2):

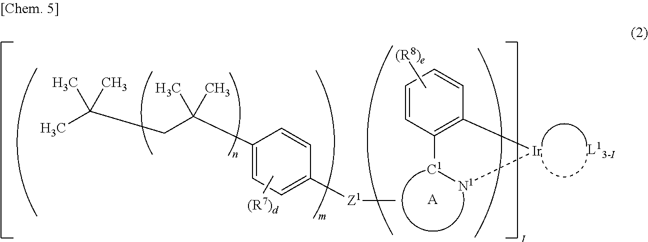

[in the above formula,
R⁷ and R⁸ are each independently any of an alkyl group having 1 to 20 carbon atoms, a (hetero) aralkyl group having 7 to 40 carbon atoms, an alkoxy group having 1 to 20 carbon atoms, a (hetero) aryloxy group having 3 to 20 carbon atoms, an alkylsilyl group having 1 to 20 carbon atoms, an arylsilyl group having 6 to 20 carbon atoms, an alkylcarbonyl group having 2 to 20 carbon atoms, an arylcarbonyl group having 7 to 20 carbon atoms, an alkylamino group having 1 to 20 carbon atoms, an arylamino group having 6 to 20 carbon atoms, and a (hetero) aryl group having 3 to 30 carbon atoms, or a combination thereof;
these groups may further have substituents, and examples of the substituent include any of a fluorine atom, a chlorine atom, a bromine atom, an alkyl group having 1 to 20 carbon atoms, a (hetero) aralkyl group having 7 to 40 carbon atoms, an alkoxy group having 1 to 20 carbon atoms, a (hetero) aryloxy group having 3 to 20 carbon atoms, an alkylsilyl group having 1 to 20 carbon atoms, an arylsilyl group having 6 to 20 carbon atoms, an alkylcarbonyl group having 2 to 20 carbon atoms, an arylcarbonyl group having 7 to 20 carbon atoms, an alkylamino group having 2 to 20 carbon atoms, an arylamino group having 6 to 20 carbon atoms, and a (hetero) aryl group having 3 to 20 carbon atoms, or a combination thereof;
in a case where a plurality of R⁷ and R⁸ are present, the plurality of R⁷ and R⁸ may be the same as or different from each other; in addition, adjacent R⁷ or R⁸ bonded to a benzene ring may be bonded to each other to form a ring that is condensed to the benzene ring;
d is an integer of 0 to 4, and e is an integer of 0 to 3;
m is an integer of 1 to 20;
n is an integer of 0 to 2;
a ring A is any of a pyridine ring, a pyrazine ring, a pyrimidine ring, an imidazole ring, an oxazole ring, a thiazole ring, a quinoline ring, an isoquinoline ring, a quinazoline ring, a quinoxaline ring, an azatriphenylene ring, and a carboline ring;
the ring A may have a substituent, and the substituent is any of a fluorine atom, a chlorine atom, a bromine atom, an alkyl group having 1 to 20 carbon atoms, a (hetero) aralkyl group having 7 to 40 carbon atoms, an alkoxy group having 1 to 20 carbon atoms, a (hetero) aryloxy group having 3 to 20 carbon atoms, an alkylsilyl group having 1 to 20 carbon atoms, an arylsilyl group having 6 to 20 carbon atoms, an alkylcarbonyl group having 2 to 20 carbon atoms, an arylcarbonyl group having 7 to 20 carbon atoms, an alkylamino group having 2 to 20 carbon atoms, an arylamino group having 6 to 20 carbon atoms, and a (hetero) aryl group having 3 to 20 carbon atoms, or a combination thereof; in addition, adjacent substituents bonded to the ring A may be bonded to each other to form a ring that is condensed to the ring A;
Z¹ represents a direct bond or an (m+1)-valent aromatic linking group;
L¹ represents an auxiliary ligand, and l is an integer of 1 to 3; and in a case where a plurality of auxiliary ligands are present, the auxiliary ligands may be different from each other or the same.]

<7>

The composition for an organic electroluminescent element according to any of <1> to <6>, in which
the functional material includes a polymer compound having a repeating unit containing a structure represented by the following formula (3):

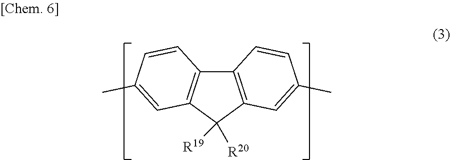

[in the formula (3), R¹⁹ and R²⁰ are each independently any of an alkyl group having 1 to 20 carbon atoms, a (hetero) aralkyl group having 7 to 40 carbon atoms, an alkoxy group having 1 to 20 carbon atoms, a (hetero) aryloxy group having 3 to 20 carbon atoms, an alkylsilyl group having 1 to 20 carbon atoms, an arylsilyl group having 6 to 20 carbon atoms, an alkylcarbonyl group having 2 to 20 carbon atoms, an arylcarbonyl group having 7 to 20 carbon atoms, an alkylamino group having 1 to 20 carbon atoms, an arylamino group having 6 to 20 carbon atoms, and a (hetero) aryl group having 3 to 30 carbon atoms, or a combination thereof; and these groups may further have substituents.]

<8>

The composition for an organic electroluminescent element according to <7>, in which
the polymer compound further has a repeating unit represented by the following formula (3-1):

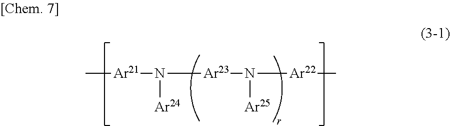

[in the formula (3-1), Ar²¹ to Ar²³ each independently represent a divalent (hetero) arylene group having 3 to 30 carbon atoms which may have a substituent;
Ar²⁴ and Ar²⁵ each independently represent a (hetero) aryl group having 3 to 30 carbon atoms which may have a substituent; and
r represents an integer of 0 to 2.]

<9>

The composition for an organic electroluminescent element according to any of <1> to <8>, in which
the second solvent is an aromatic ether.

<10>

The composition for an organic electroluminescent element according to any of <1> to <8>, in which
the second solvent is an aromatic ester.

<11>

A method for producing an organic electroluminescent element, containing:
a step of forming an emission layer by a wet-process film formation method using the composition for an organic electroluminescent element according to any of <1> to <10>.

<12>

An organic electroluminescent element including:
an emission layer formed using the composition for an organic electroluminescent element according to any of <1> to <10>.

<13>

A display device including:
the organic electroluminescent element according to <12>.

<14>

An illuminator including:
the organic electroluminescent element according to <12>.

### Advantageous Effects of Invention

Since the composition for an organic electroluminescent element according to the present invention is excellent in stability of liquid physical properties, in particular, in surface tension stability of the ink, even when the composition for an organic electroluminescent element is used for production of an organic electroluminescent element after being stored for a long period of time, it is possible to obtain a display device or an illuminator in which a decrease in emission efficiency or driving lifetime is small and unevenness is small because a change in liquid physical properties is small. That is, the composition for an organic electroluminescent element according to the present invention is a composition that can be applied to large-area coating and can be stored for a long period of time.

In the present invention, an action mechanism that achieves such an effect is presumed as follows.

Since the composition for an organic electroluminescent element according to the present invention uses alkylated naphthalene or diphenyl alkane, which does not volatilize under normal temperature and normal pressure, as a solvent, the composition for an organic electroluminescent element can be applied to a large area without volatilization of the solvent even when a coating step requires time. In addition, since the composition for an organic electroluminescent element according to the present invention contains the compound represented by the formula (1) which is a phenol derivative, deterioration of the functional material is prevented even when the ink is stored for a long period of time. Further, since the composition for an organic electroluminescent element according to the present invention contains an aromatic ether and/or an aromatic ester as a solvent, it is possible to reduce a change in liquid physical properties due to oxidation of the phenol derivative.

When the phenol derivative is contained in the ink, deterioration of the functional material due to oxidation is prevented, but it is considered that the phenol derivative itself is oxidized. In a case where phenols are oxidized, the phenols are generally converted into phenoxy radicals by proton transfer or hydrogen atom transfer after one-electron oxidation. Thereafter, although it is unclear whether the phenoxy radicals are further changed into other substances such as benzoquinones and peroxides in the ink, a phenolic hydroxy group is not present in any case. The phenolic hydroxy group exhibits acidity due to a resonance effect of an aromatic ring in addition to hydrogen bonding properties, but these properties are considered to change greatly due to oxidation.

When alkylated naphthalene or diphenyl alkane is used as the solvent, it is considered that even when a content of the phenol derivative is small, the oxidation of the phenol derivative has an influence on the liquid physical properties. However, when an aromatic ether and/or an aromatic ester having an oxygen atom and a non-conjugated electron pair is used as the second solvent, it is possible to prevent the change in liquid physical properties.

### BRIEF DESCRIPTION OF DRAWINGS

The FIGURE is a cross-sectional view schematically showing an example of a structure of an organic electroluminescent element according to the present invention.

### DESCRIPTION OF EMBODIMENTS

Hereinafter, embodiments of the present invention will be described in detail. The present invention is not limited to the following embodiments, and various modifications can be made within the scope of the gist of the present invention.

In the present description, the (hetero) aralkyl group, the (hetero) aryloxy group, and the (hetero) aryl group represent an aralkyl group which may contain a heteroatom, an aryloxy group which may contain a heteroatom, and an aryl group which may contain a heteroatom, respectively. The expression “may contain a heteroatom” means that one or two or more of carbon atoms forming a main framework of an aryl group, an aralkyl group, or an aryloxy group are substituted with a heteroatom. Examples of the heteroatom include a nitrogen atom, an oxygen atom, a sulfur atom, a phosphorus atom, and a silicon atom. Among these, a nitrogen atom is preferable from the viewpoint of durability. The same applies to the (hetero) arylene group.

In the present description, an “aromatic linking group” refers not only to an aromatic hydrocarbon linking group, that is, a linking group having an aromatic hydrocarbon ring, but also to a heteroaromatic linking group, that is, an aromatic linking group in a broad sense including a linking group having a heteroaromatic ring.

### [Composition for Organic Electroluminescent Element]

The composition for an organic electroluminescent element according to the present invention contains a functional material, a compound represented by the following formula (1), alkylated naphthalene or diphenyl alkane as a first solvent, and an aromatic ether and/or an aromatic ester as a second solvent.

That is, a composition for an organic electroluminescent element according to a first aspect of the present invention contains a functional material, a compound represented by the following formula (1), alkylated naphthalene as a first solvent, and an aromatic ether and/or an aromatic ester as a second solvent.

In addition, a composition for an organic electroluminescent element according to a second aspect of the present invention contains a functional material, a compound represented by the following formula (1), diphenyl alkane as a first solvent, and an aromatic ether and/or an aromatic ester as a second solvent.

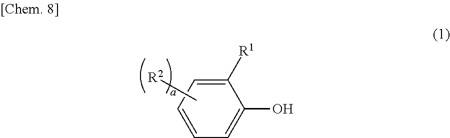

[In the above formula, a is an integer of 0 to 4, R¹ and R² each independently represent an alkyl group having 1 to 12 carbons or an alkoxy group having 1 to 12 carbons; and in a case where a plurality of R² are present, the plurality of R² may be the same as or different from each other.]

### [Functional Material]

The composition for an organic electroluminescent element according to the present invention contains a functional material. The functional material is a luminescent material or a charge-transporting material contained in the emission layer of the organic electroluminescent element.

The composition for an organic electroluminescent element according to the present invention preferably contains a phosphorescent organometallic complex as the functional material from the viewpoint that energy under an excited triplet state can contribute to light emission, and among these, preferably contains an iridium complex which is an organometallic complex containing iridium as a central element.

### [Iridium Complex]

The iridium complex contained in the composition for an organic electroluminescent element according to the present invention is preferably represented by the following formula (2) from the viewpoint of high solubility in an organic solvent and high heat resistance.

### (Formula (2))

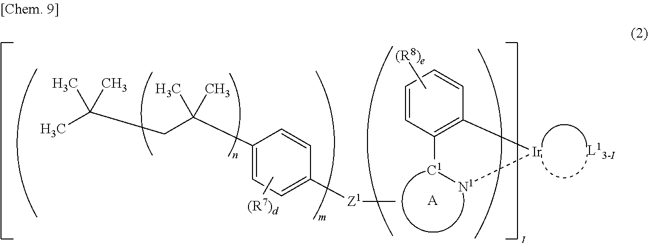

[In the above formula, R⁷ and R⁸ are each independently any of an alkyl group having 1 to 20 carbon atoms, a (hetero) aralkyl group having 7 to 40 carbon atoms, an alkoxy group having 1 to 20 carbon atoms, a (hetero) aryloxy group having 3 to 20 carbon atoms, an alkylsilyl group having 1 to 20 carbon atoms, an arylsilyl group having 6 to 20 carbon atoms, an alkylcarbonyl group having 2 to 20 carbon atoms, an arylcarbonyl group having 7 to 20 carbon atoms, an alkylamino group having 1 to 20 carbon atoms, an arylamino group having 6 to 20 carbon atoms, and a (hetero) aryl group having 3 to 30 carbon atoms, or a combination thereof; these groups may further have substituents; in a case where a plurality of R⁷ and R⁸ are present, the plurality of R⁷ and R⁸ may be the same as or different from each other; in addition, adjacent R⁷ or R⁸ bonded to a benzene ring may be bonded to each other to form a ring that is condensed to the benzene ring;

d is an integer of 0 to 4, and e is an integer of 0 to 3;

m is an integer of 1 to 20;

n is an integer of 0 to 2;

a ring A is any of a pyridine ring, a pyrazine ring, a pyrimidine ring, an imidazole ring, an oxazole ring, a thiazole ring, a quinoline ring, an isoquinoline ring, a quinazoline ring, a quinoxaline ring, an azatriphenylene ring, and a carboline ring;

the ring A may have a substituent, and the substituent is any of a fluorine atom, a chlorine atom, a bromine atom, an alkyl group having 1 to 20 carbon atoms, a (hetero) aralkyl group having 7 to 40 carbon atoms, an alkoxy group having 1 to 20 carbon atoms, a (hetero) aryloxy group having 3 to 20 carbon atoms, an alkylsilyl group having 1 to 20 carbon atoms, an arylsilyl group having 6 to 20 carbon atoms, an alkylcarbonyl group having 2 to 20 carbon atoms, an arylcarbonyl group having 7 to 20 carbon atoms, an alkylamino group having 2 to 20 carbon atoms, an arylamino group having 6 to 20 carbon atoms, and a (hetero) aryl group having 3 to 20 carbon atoms, or a combination thereof; in addition, adjacent substituents bonded to the ring A may be bonded to each other to form a ring that is condensed to the ring A;

Z¹ represents a direct bond or an (m+1)-valent aromatic linking group;

L¹ represents an auxiliary ligand, and l is an integer of 1 to 3; and in a case where a plurality of auxiliary ligands are present, the auxiliary ligands may be different from each other or the same.]

Hereinafter, preferred R⁷, R⁸, d, e, m, n, ring A, Z¹, and L¹ will be described.

(R⁷ and R⁸)

In the formula (2), from the viewpoint of durability, R⁷ and R⁸ are each independently preferably an alkyl group having 1 to 20 carbon atoms, a (hetero) aralkyl group having 7 to 40 carbon atoms, an arylamino group having 6 to 20 carbon atoms, or a (hetero) aryl group having 3 to 30 carbon atoms, and more preferably an alkyl group having 1 to 20 carbon atoms, a (hetero) aralkyl group having 7 to 40 carbon atoms, or a (hetero) aryl group having 3 to 20 carbon atoms.

Adjacent two R⁷ and adjacent two R⁸ may be linked to each other to form a ring that is condensed to a benzene ring to which the groups are bonded.

In a case where R⁷ and R⁸ further have substituents, examples of the substituent include any of a fluorine atom, a chlorine atom, a bromine atom, an alkyl group having 1 to 20 carbon atoms, a (hetero) aralkyl group having 7 to 40 carbon atoms, an alkoxy group having 1 to 20 carbon atoms, a (hetero) aryloxy group having 3 to 20 carbon atoms, an alkylsilyl group having 1 to 20 carbon atoms, an arylsilyl group having 6 to 20 carbon atoms, an alkylcarbonyl group having 2 to 20 carbon atoms, an arylcarbonyl group having 7 to 20 carbon atoms, an alkylamino group having 2 to 20 carbon atoms, an arylamino group having 6 to 20 carbon atoms, and a (hetero) aryl group having 3 to 20 carbon atoms, or a combination thereof.

(d and e)

d is preferably 0 from the viewpoint of ease of production, preferably 1 or 2 from the viewpoint of improvement of solubility, and still more preferably 1.

In a case where adjacent two R⁷ are linked to each other to form a ring, d is preferably 2.

e is preferably 0 from the viewpoint of ease of production, preferably 1 or 2 from the viewpoint of improvement of durability and solubility, and still more preferably 1.

In a case where adjacent two R⁸ are linked to each other to form a ring, e is preferably 2 or 3.

(m)

Since a phenyl group having a t-butyl group at a terminal improves the solubility in an organic solvent, m is preferably 2 or more. The phenyl group having a t-butyl group at the terminal is less involved in charge transport and light emission, and therefore, when an amount of the phenyl group is too large, there is a concern that the driving voltage may increase or the emission efficiency may decrease. Therefore, m is preferably 8 or less, and still more preferably 4 or less. From the viewpoint of high solubility, high charge transportability, high emission efficiency, and ease of synthesis, m is most preferably 2.

The iridium complex represented by the formula (2) preferably has 4 or more, particularly 6 or more and 48 or less, particularly 24 or less of such a terminal t-butyl group in the whole iridium complex from the viewpoint of achieving both solubility as well as low driving voltage and high emission efficiency.

(n)

n is preferably 0 or 1 from the viewpoint of ease of production. From the viewpoint of less concern that the driving voltage increases, n is preferably 0. From the viewpoint of improvement of solubility, n is preferably 1 or 2.

### (Ring A)

The ring A is preferably a pyridine ring, a pyrimidine ring, or an imidazole ring, and still more preferably a pyridine ring, from the viewpoint of durability.

A hydrogen atom on the ring A is preferably substituted with at least one of an alkyl group having 1 to 20 carbon atoms, a (hetero) aralkyl group having 7 to 40 carbon atoms, and a (hetero) aryl group having 3 to 20 carbon atoms from the viewpoint of durability and improvement of solubility.

The hydrogen atom on the ring A is preferably unsubstituted from the viewpoint of ease of production.

The hydrogen atom on the ring A is preferably substituted with a phenyl group or a naphthyl group which may have a substituent, from the viewpoint of improvement of emission efficiency because excitons are easily generated when used in an organic electroluminescent element.

When substituents on the ring A are bonded to each other to form a condensed ring that is condensed to the ring A, the ring A forms at least one of a quinoline ring, an isoquinoline ring, a quinazoline ring, a quinoxaline ring, an azatriphenylene ring, and a carboline ring, resulting in a longer emission wavelength, so that the ring A is useful for use in red light emission. Among these, the ring A preferably forms at least one of a quinoline ring, an isoquinoline ring, and a quinazoline ring, from the viewpoint of durability and red light emission.

### (Z¹)

Z¹ is preferably a direct bond from the viewpoint of ease of production.

Z¹ is preferably an (m+1)-valent aromatic linking group from the viewpoint of less concern that the driving voltage increases.

In a case where m is 1, Z¹ is preferably a phenylene group, a biphenylene group, a terphenylene group, or a fluorenediyl group, and particularly preferably a p-phenylene group, from the viewpoint of durability.

In a case where m is 2 or more, Z¹ preferably contains a benzene ring in which the 1-, 3-, and 5-sites are bonding sites or a triazine ring in which the 2-, 4-, 6-sites are bonding sites, from the viewpoint of durability.

Z¹ preferably contains a trivalent group represented by the following formula (2-2A) or (2-2B).

### (Formula (2-2A) and Formula (2-2B))

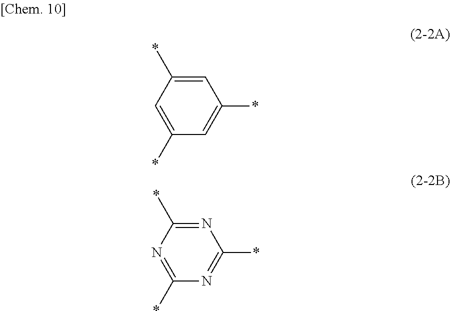

“*” in the formulae (2-2A) and (2-2B) represents bonding to a structure adjacent thereto.

The group represented by the formula (2-2A) or (2-2B) is still more preferably bonded to a benzene ring or the ring A bonded to iridium.

As Z¹, a still more preferred structure thereof is a structure in which m is 2, and Z¹ is a trivalent group represented by the formula (2-2A) or (2-2B).

### (L¹: Auxiliary Ligand)

L¹ is an auxiliary ligand. Although not particularly limited, L′ is preferably a monovalent bidentate ligand, and more preferably selected from ligands represented by the following formula (2A), (2B), or (2C).

In the following formulae (2A) to (2C), a broken line represents a coordinate bond.

In a case where l is 1 and there are two auxiliary ligands L′, the auxiliary ligands L′ may be the same as or different from each other.

When l is 3, L′ does not exist.

### (Formula (2A) to Formula (2C))

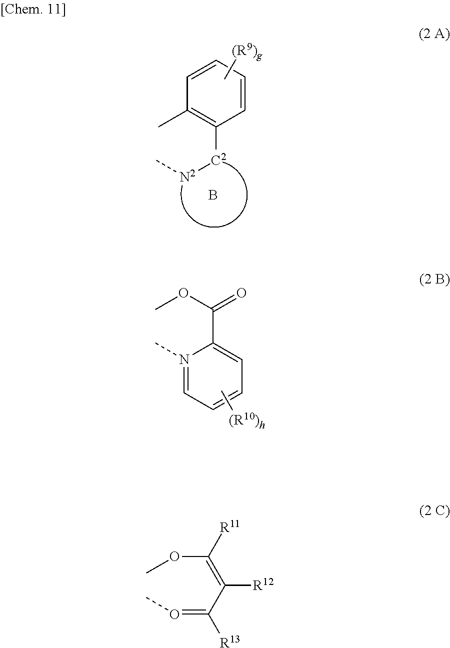

(R⁹ and R¹⁰)

In the above formulae (2A) and (2B), R⁹ and R¹⁰ are selected from the same group as R⁷ and R⁸, and preferred examples thereof are also the same.

(g and h)

g is an integer of 0 to 4. h is an integer of 0 to 4. g and h are preferably 0 from the viewpoint of ease of production, preferably 1 or 2 from the viewpoint of improvement of solubility, and still more preferably 1.

### (Ring B)

The ring B is any of a pyridine ring, a pyrimidine ring, an imidazole ring, a quinoline ring, an isoquinoline ring, a quinazoline ring, a quinoxaline ring, an azatriphenylene ring, a carboline ring, a benzothiazole ring, and a benzoxazole ring, and may have a substituent.

From the viewpoint of durability, the ring B is preferably any of a pyridine ring, a pyrimidine ring, or an imidazole ring, and still more preferably a pyridine ring.

A hydrogen atom on the ring B is preferably substituted with at least one of an alkyl group having 1 to 20 carbon atoms, a (hetero) aralkyl group having 7 to 40 carbon atoms, and a (hetero) aryl group having 3 to 20 carbon atoms from the viewpoint of durability and improvement of solubility.

The hydrogen atom on the ring B is preferably unsubstituted from the viewpoint of ease of production.

The hydrogen atom on the ring B is preferably substituted with a phenyl group or a naphthyl group which may have a substituent, from the viewpoint of improvement of emission efficiency because excitons are easily generated when used in an organic electroluminescent element.

When substituents on the ring B are bonded to each other to form a condensed ring that is condensed to the ring B, the ring B forms at least one of a quinoline ring, an isoquinoline ring, a quinazoline ring, a quinoxaline ring, an azatriphenylene ring, and a carboline ring, resulting in easy generation of excitons on an assist dopant, so that the ring B is preferable from the viewpoint of improvement of emission efficiency. Among these, the ring B preferably forms a quinoline ring, an isoquinoline ring, or a quinazoline ring, from the viewpoint of durability and red light emission.

(R¹¹ to R¹³)

In the formula (2C), R¹¹ to R¹³ each independently represent a hydrogen atom, an alkyl group having 1 to 20 carbon atoms which may be substituted with a fluorine atom, a phenyl group which may be substituted with an alkyl group having 1 to 20 carbon atoms, or a halogen atom. More preferably, R¹¹ and R¹³ are a methyl group or a t-butyl group, and R¹² is a hydrogen atom, an alkyl group having 1 to 20 carbon atoms, or a phenyl group.

### (Preferred Formula (2))

The compound represented by the formula (2) is also preferably a compound represented by the following formula (2-2) in which adjacent R⁸ are bonded to each other to form a fluorene ring.

### (Formula (2-2))

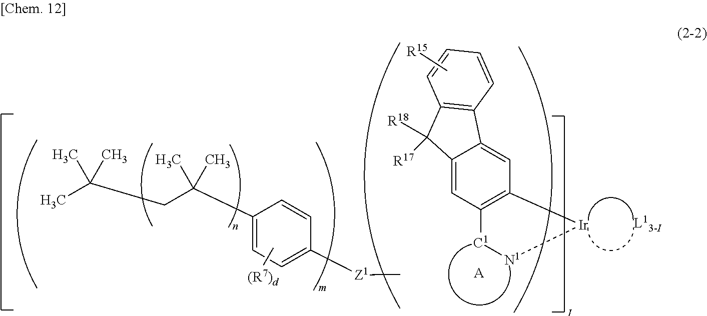

[In the formula (2-2), R⁷, d, m, n, ring A, Z¹, L¹, and 1 have the same meaning as R⁷, d, m, n, ring A, Z¹, L¹, 1 in the formula (2); and

R¹⁵ to R¹⁷ are substituents.]

### (R¹⁵)

Examples of R¹⁵ include the above-described substituents which R⁸ may have. More preferably, R¹⁵ is an alkyl group having 1 to 20 carbon atoms, or an aromatic hydrocarbon group having 6 to 30 carbon atoms which may be substituted with one or two alkyl groups having 1 to 20 carbon atoms. Here, the aromatic hydrocarbon group having 6 to 30 carbon atoms is a monocyclic ring, a bicyclic condensed ring, or a tricyclic condensed ring, or a group in which a plurality of monocyclic rings, bicyclic condensed rings, or tricyclic condensed rings are linked. R¹⁵ is still more preferably an alkyl group having 1 to 20 carbon atoms, and particularly preferably an alkyl group having 1 to 8 carbon atoms.

(R¹⁶ and R¹⁷)

R¹⁶ and R¹⁷ are a part of R⁸ or a substituent which R⁸ may have, and are each preferably independently an alkyl group having 1 to 12 carbons, an aromatic hydrocarbon group having 6 to 20 carbons which may be substituted with one or two alkyl groups having 1 to 12 carbons, an alkoxy group having 1 to 12 carbons, or an aromatic hydrocarbon group having 6 to 20 carbons which may be substituted with one or two alkoxy groups having 1 to 12 carbons. Here, the aromatic hydrocarbon group having 6 to 20 carbon atoms is a monocyclic ring, a bicyclic condensed ring, or a tricyclic condensed ring, or a group in which a plurality of monocyclic rings, bicyclic condensed rings, or tricyclic condensed rings are linked. R¹⁶ and R¹⁷ are each still more preferably independently an alkyl group having 1 to 8 carbon atoms or an aromatic hydrocarbon group having 6 or 12 carbon atoms which may be substituted with one or two alkyl groups having 1 to 8 carbon atoms, and particularly preferably an alkyl group having 1 to 8 carbon atoms or an aromatic hydrocarbon group having 6 carbon atoms which may be substituted with one or two alkyl groups having 1 to 8 carbon atoms. Here, an aromatic hydrocarbon structure having 6 carbon atoms is a benzene structure, and an aromatic hydrocarbon structure having 12 carbon atoms is a biphenyl structure.

### Preferred Specific Examples

Preferred specific examples of the compound represented by the formula (2) which is an iridium complex that may be contained as a functional material in the composition for an organic electroluminescent element according to the present invention are shown below.

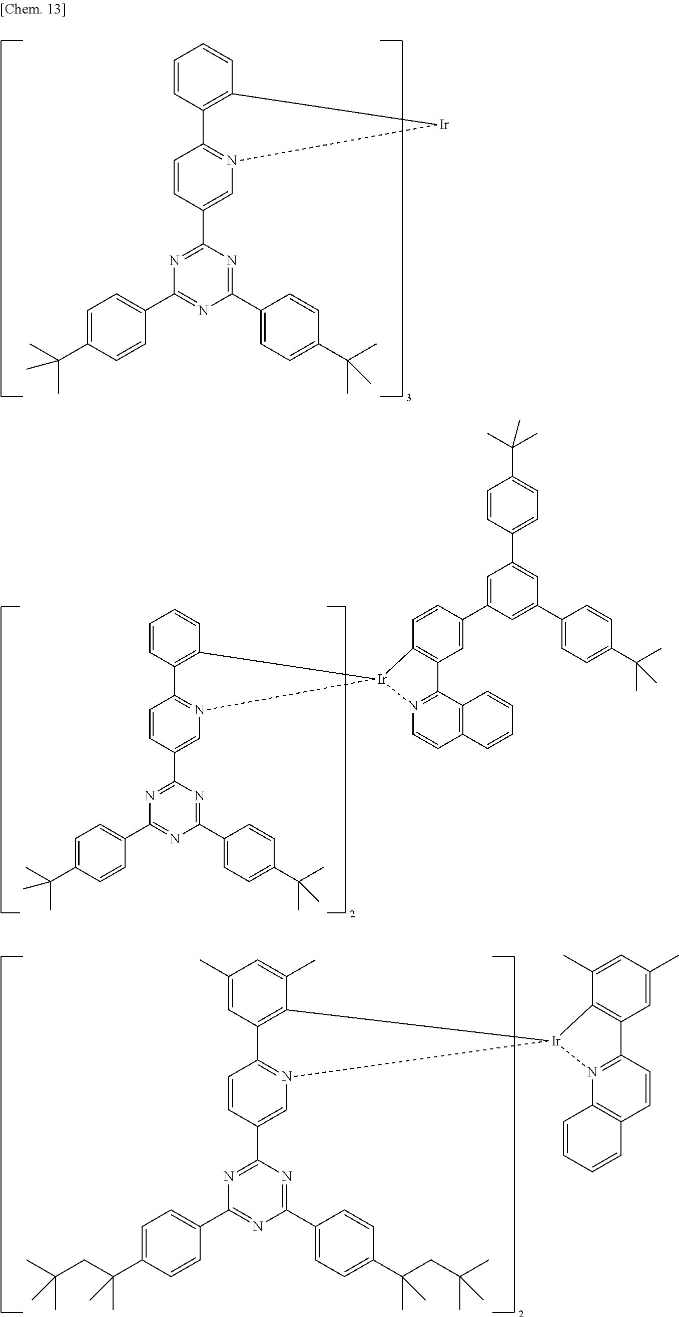

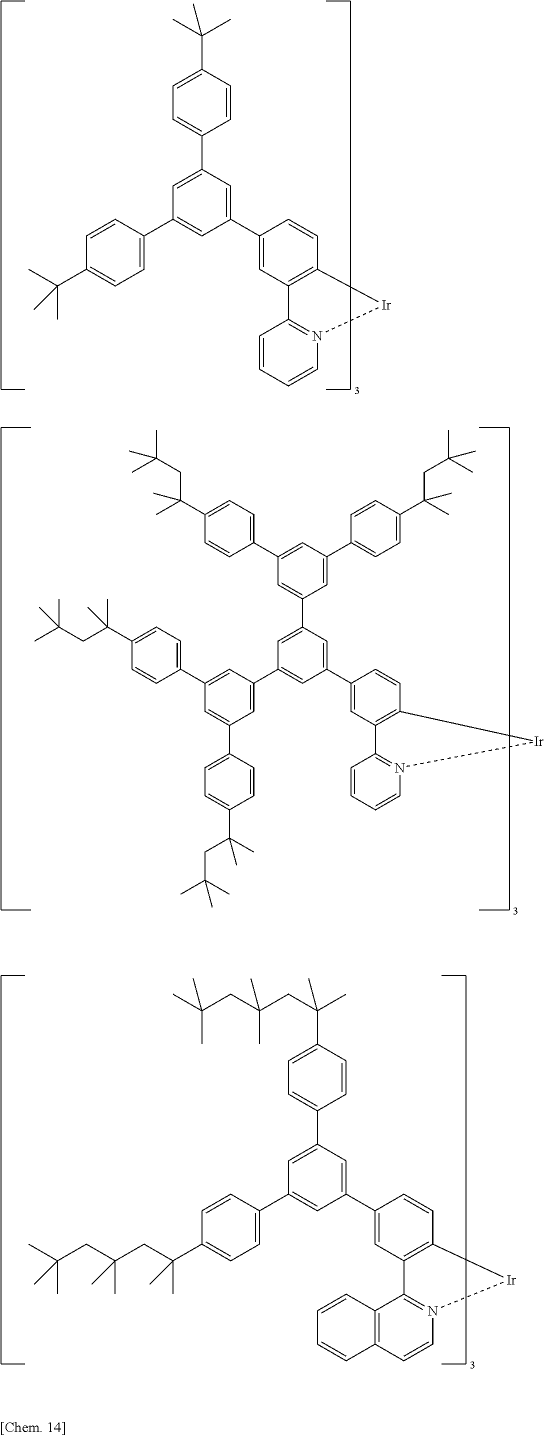

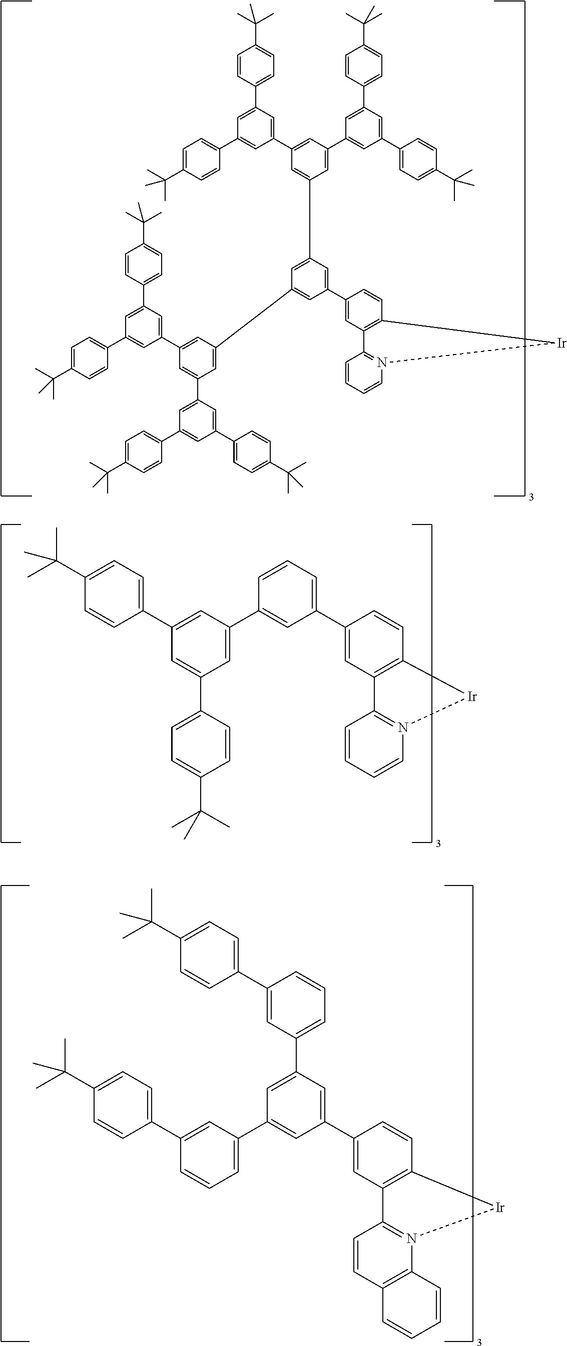

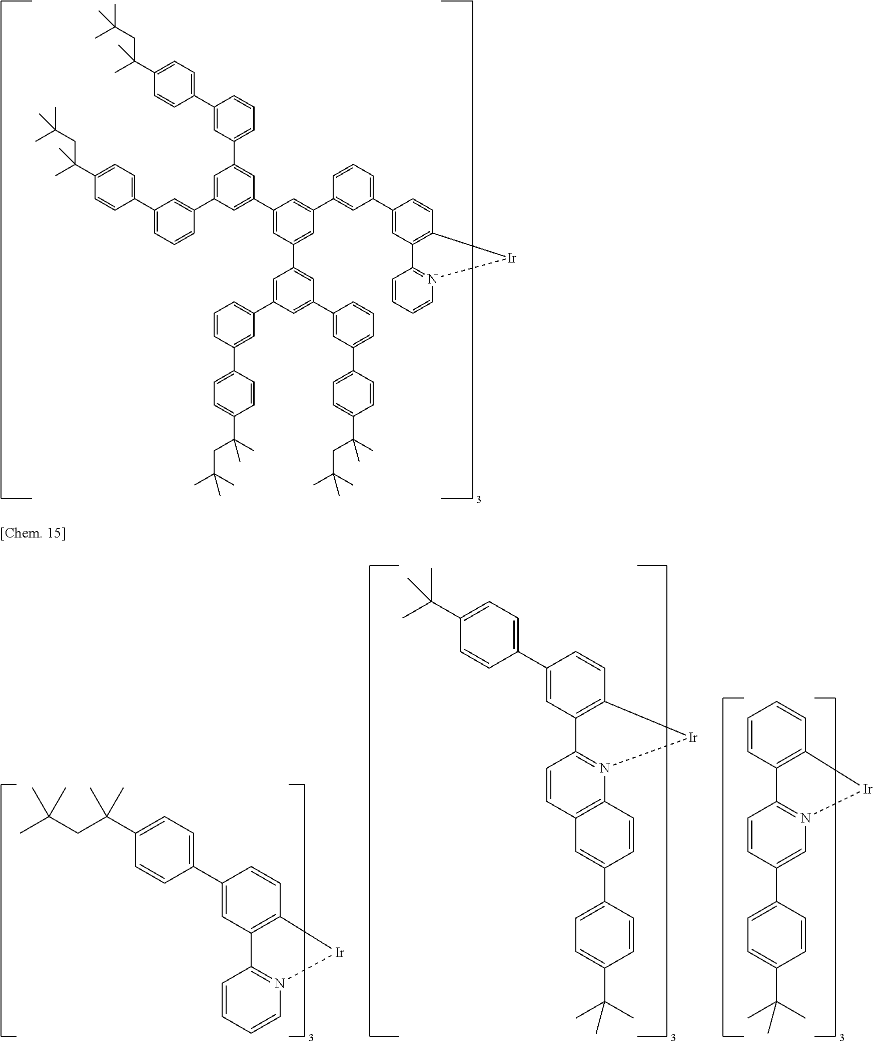

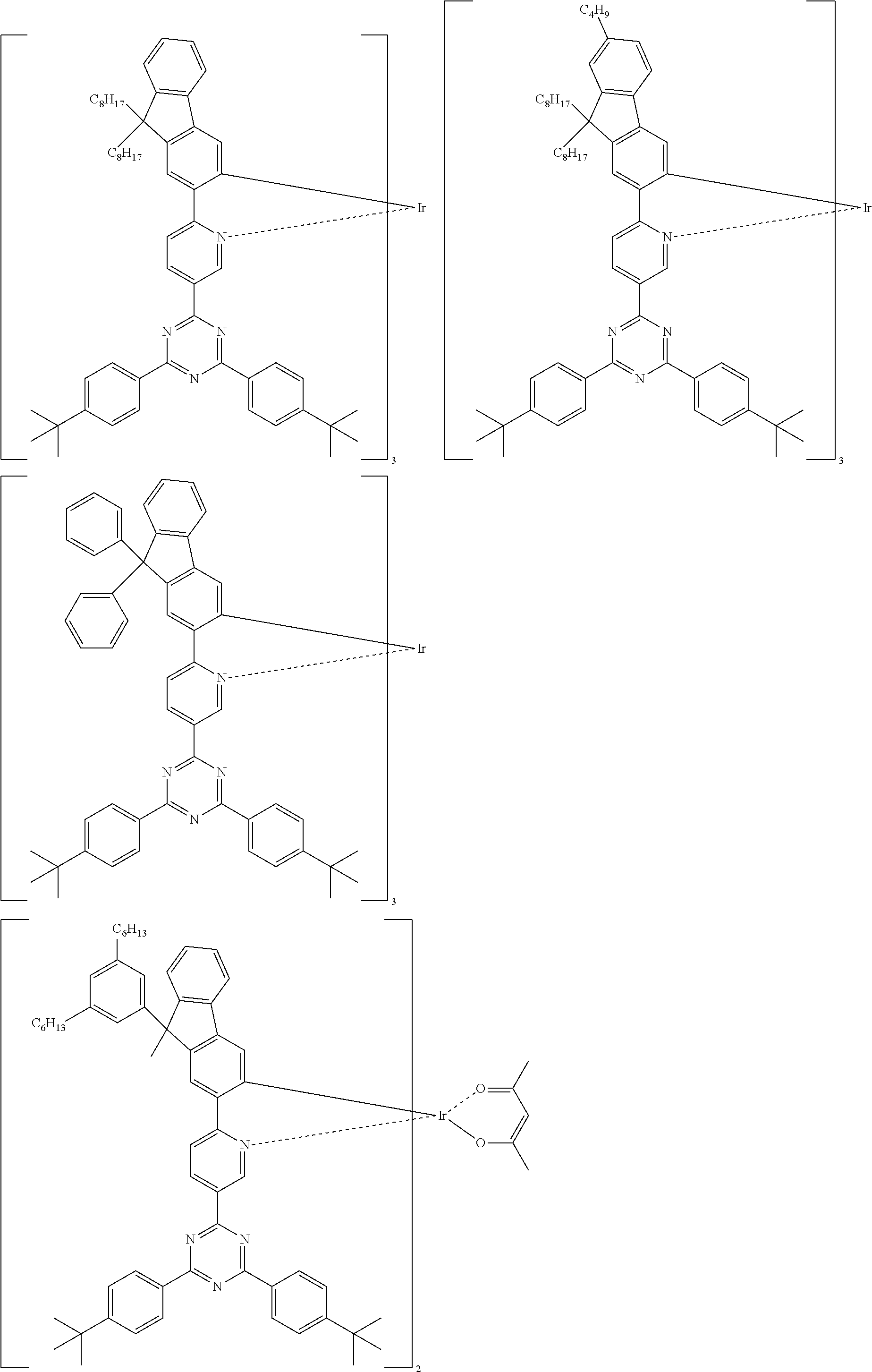

The composition for an organic electroluminescent element according to the present invention may contain only one type of the iridium complexes, or may contain two or more types thereof.

### [Charge-Transporting Material]

The charge-transporting material which may be contained as a functional material in the composition for an organic electroluminescent element according to the present invention is a material having positive charge (hole) transportability or negative charge (electron) transportability, is not particularly limited as long as the effect of the present invention is not impaired, and a known material can be applied.

As the charge-transporting material, a compound or the like commonly used for the emission layer of an organic electroluminescent element can be used, and in particular, a compound used as a host material of the emission layer is preferable.

Specific examples of the charge-transporting material include compounds exemplified as hole-transporting compounds of a hole injection layer 3 to be described later, such as an aromatic amine-based compound, a phthalocyanine-based compound, a porphyrin-based compound, an oligothiophene-based compound, a polythiophene-based compound, a benzylphenyl-based compound, a compound in which a tertiary amine is linked via a fluorene group, a hydrazone-based compound, a silazane-based compound, a silanamine-based compound, a phosphamine-based compound, and a quinacridone-based compound, and include an electron-transporting compound such as an anthracene-based compound, a pyrene-based compound, a carbazole-based compound, a pyridine-based compound, a phenanthroline-based compound, an oxadiazole-based compound, and a silole-based compound.

In addition, for example, compounds exemplified as hole-transporting compounds of a hole transport layer 4 to be described later can also be preferably used, such as aromatic diamines containing two or more tertiary amines and having two or more condensed aromatic rings substituted with nitrogen atoms, represented by 4,4′-bis[N-(1-naphthyl)-N-phenylamino]biphenyl (Japanese Patent Laid-Open No. H5-234681), aromatic amine-based compounds having burst such a star structure, as 4,4′,4″-tris(1-naphthylphenylamino)triphenylamine (J. Lumin., Vol. 72-74, p. 985, 1997), aromatic amine-based compounds formed of tetramers of triphenylamine (Chem. Commun., p. 2175, 1996), fluorene-based compounds such as 2,2′,7,7′-tetrakis-(diphenylamino)-9,9′-spirobifluorene (Synth. Metals, Vol. 91, p. 209, 1997), and carbazole-based compounds such as 4,4′-N,N′-dicarbazole biphenyl. Other examples thereof include oxadiazole-based compounds such as 2-(4-biphenylyl)-5-(p-tert-butylphenyl)-1,3,4-oxadiazole (tBu-PBD) and 2,5-bis(1-naphthyl)-1,3,4-oxadiazole (BND), silole-based compounds such as 2,5-bis(6′-(2′,2″-bipyridyl))-1,1-dimethyl-3,4-diphenylsilole (PyPySPyPy), and phenanthroline-based compounds such as bathophenanthroline (BPhen) and 2,9-dimethyl-4,7-diphenyl-1,10-phenanthroline (BCP, bathocuproine).

The charge-transporting material which may be contained in the composition for an organic electroluminescent element according to the present invention is preferably a polymer compound having a repeating unit (hereinafter, may be referred to as “repeating unit (3)”) containing a structure represented by the following formula (3) from the viewpoint of film formability.

### (Repeating Unit Represented by Formula (3))

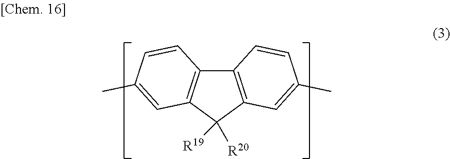

[In the formula (3), R¹⁹ and R²⁰ are each independently any of an alkyl group having 1 to 20 carbon atoms, a (hetero) aralkyl group having 7 to 40 carbon atoms, an alkoxy group having 1 to 20 carbon atoms, a (hetero) aryloxy group having 3 to 20 carbon atoms, an alkylsilyl group having 1 to 20 carbon atoms, an arylsilyl group having 6 to 20 carbon atoms, an alkylcarbonyl group having 2 to 20 carbon atoms, an arylcarbonyl group having 7 to 20 carbon atoms, an alkylamino group having 1 to 20 carbon atoms, an arylamino group having 6 to 20 carbon atoms, and a (hetero) aryl group having 3 to 30 carbon atoms, or a combination thereof; and these groups may further have substituents.]

(R¹⁹ and R²⁰)

In the formula (3), R¹⁹ and R²⁰ are each independently preferably an alkyl group having 1 to 20 carbon atoms or a (hetero) aralkyl group having 7 to 40 carbon atoms from the viewpoint of solubility. R¹⁹ and R²⁰ are each independently preferably a (hetero) aryl group having 3 to 30 carbon atoms from the viewpoint of heat resistance.

The polymer compound having the repeating unit (3) which may be contained in the composition for an organic electroluminescent element according to the present invention preferably contains, in addition to the repeating unit (3), a repeating unit containing a structure represented by the following formula (3-1) (hereinafter, may be referred to as “repeating unit (3-1)”). In this case, the repeating unit (3) may be included in the following repeating unit (3-1).

### (Formula (3-1))

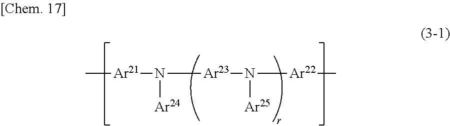

[In the formula (3-1), Ar²¹ to Ar²³ each independently represent a divalent (hetero) arylene group having 3 to 30 carbon atoms which may have a substituent;

Ar²⁴ and Ar²⁵ each independently represent a (hetero) aryl group having 3 to 30 carbon atoms which may have a substituent; and

r represents an integer of 0 to 2.]

(Ar²¹ to Ar²⁵)

From the viewpoint of durability, Ar²¹ to Ar²³ are each independently preferably a phenylene group, a biphenylene group, a terphenylene group, a fluorenediyl group, or a divalent group having 30 or fewer carbon atoms obtained by optionally selecting and linking these groups, and particularly preferably a p-phenylene group or a biphenylene group. These groups may have substituents.

In a case where the formula (3-1) includes the structure represented by the formula (3), at least one selected from among Ar²¹, Ar²², and at least one Ar²³ when r is 1 or more is a fluorenyl group represented by the formula (3) and may have a substituent at the 9,9′-site.

From the viewpoint of durability, Ar²⁴ and Ar²⁵ are each independently preferably a phenyl group, a biphenyl group, a terphenyl group, or a fluorenyl group, and particularly preferably a phenyl group or a fluorenyl group. These groups may have substituents.

The polymer compound having the repeating unit (3) which may be contained in the composition for an organic electroluminescent element according to the present invention may contain only one type of the repeating unit (3), or may contain two or more types thereof. In addition, the polymer compound having the repeating unit (3) may contain only one type of the repeating unit (3-1), or may contain two or more types thereof.

### (Molecular Weight)

A weight average molecular weight (Mw) of the polymer compound having the repeating unit (3) which may be contained in the composition for an organic electroluminescent element according to the present invention is generally 2,000,000 or less, preferably 500,000 or less, more preferably 100,000 or less, still more preferably 50,000 or less, and is generally 2,500 or more, preferably 5,000 or more, more preferably 10,000 or more, still more preferably 20,000 or more.

When the weight average molecular weight is equal to or less than the above upper limit value, the solubility in a solvent is excellent, and the film formability is also excellent. When the weight average molecular weight is equal to or greater than the above lower limit value, a glass transition temperature, a melting point, and a vaporization temperature of the polymer compound are high, and the heat resistance is excellent.

A number average molecular weight (Mn) of the polymer compound having the repeating unit (3) which may be contained in the composition for an organic electroluminescent element according to the present invention is generally 1,000,000 or less, preferably 250,000 or less, more preferably 50,000 or less, still more preferably 25,000 or less, and is generally 2,000 or more, preferably 4,000 or more, more preferably 8,000 or more, still more preferably 15,000 or more.

Dispersity (Mw/Mn) of the polymer compound having the repeating unit (3) which may be contained in the composition for an organic electroluminescent element according to the present invention is preferably 3.5 or less, still more preferably 2.5 or less, and particularly preferably 2.0 or less. Since a value of the dispersity is preferably small, a lower limit value thereof is ideally 1. When the dispersity of the polymer compound is equal to or less than the above upper limit value, purification is easy, and the solubility in a solvent and charge-transporting ability are excellent.

The weight average molecular weight of the polymer compound is generally determined by size exclusion chromatography (SEC) measurement. In the SEC measurement, an elution time is shorter for a higher molecular weight component, and the elution time is longer for a lower molecular weight component. The weight average molecular weight is calculated by converting an elution time of a sample into a molecular weight using a calibration curve calculated based on an elution time of polystyrene (standard sample) having a known molecular weight. The number average molecular weight is also obtained in the same manner.

A method for producing the polymer compound having the repeating unit (3) which may be contained in the composition for an organic electroluminescent element according to the present invention is not particularly limited, and any method can be used as long as the polymer compound having the repeating unit (3) is obtained. For example, the production can be executed by a polymerization method by Suzuki reaction, a polymerization method by Grignard reaction, a polymerization method by Yamamoto reaction, a polymerization method by Ullmann reaction, a polymerization method by Buchwald-Hartwig reaction, or the like.

### [Phenol Derivative]

The composition for an organic electroluminescent element according to the present invention contains a phenol derivative which is a compound represented by the following formula (1).

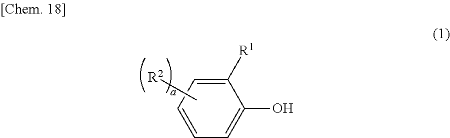

[In the above formula, a is an integer of 0 to 4, R¹ and R² each independently represent an alkyl group having 1 to 12 carbons or an alkoxy group having 1 to 12 carbons; and in a case where a plurality of R² are present, the plurality of R² may be the same as or different from each other.]

In the compound represented by the formula (1), the presence of an alkyl group or an alkoxy group, which is an electron-donating group at the o-site of the hydroxy group, causes an oxidation-reduction potential of the compound represented by the formula (1) to shift to a negative side, a HOMO to become shallow, and the compound itself to be easily oxidized, and therefore, oxidation of the functional material contained therein is simultaneously prevented.

(a)

a is preferably 1 or 2 from the viewpoint of achieving an appropriate oxidation-reduction potential.

(R¹ and R²)

When R¹ and R² are alkyl groups having 1 to 12 carbon atoms, examples thereof include a methyl group, an ethyl group, a propyl group, an isopropyl group, a butyl group, an isobutyl group, an s-butyl group, a t-butyl group, a pentyl group, an isopentyl group, a hexyl group, a cyclohexyl group, a heptyl group, an octyl group, a 2-ethylhexyl group, a nonyl group, a decyl group, an undecyl group, and a dodecyl group.

When R¹ and R² are alkoxy groups having 1 to 12 carbon atoms, examples thereof include a methoxy group, an ethoxy group, a propoxy group, an isopropoxy group, a butoxy group, an isobutoxy group, an s-butoxy group, a t-butoxy group, a pentyloxy group, an isopentyloxy group, a hexyloxy group, a cyclohexyloxy group, a heptyloxy group, an octyloxy group, a 2-ethylhexyloxy group, a nonyloxy group, a decyloxy group, an undecyloxy group, and a dodecyloxy group.

R¹ and R² are each preferably a secondary or tertiary alkyl group, and more preferably a tertiary alkyl group, from the viewpoint of having a large steric hindrance, preventing a coupling reaction between phenoxy radicals generated after oxidation, and capable of functioning as an antioxidant again. The o-site of the hydroxy group is preferably a t-butyl group that is a minimum tertiary alkyl group, from the viewpoint that the t-butyl group is less likely to remain in the emission layer after film formation because the t-butyl group is inexpensive and has a small molecular weight.

Two of the o-sites of the hydroxy group are preferably both alkyl groups or alkoxy groups from the viewpoint of achieving an appropriate oxidation-reduction potential and achieving high stability of phenoxy radicals generated after oxidation. That is, the composition for an organic electroluminescent element according to the present invention preferably contains a compound represented by the following formula (1-1) as the compound represented by the formula (1).

### (Compound Represented by Formula (1-1))

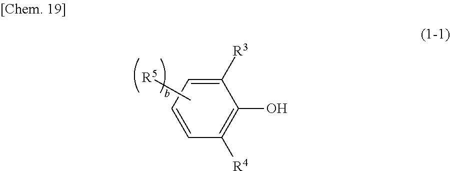

[In the above formula, b is an integer of 0 to 3, R³, R⁴, and R⁵ each independently represent an alkyl group having 1 to 12 carbons or an alkoxy group having 1 to 12 carbons; and in a case where a plurality of R⁵ are present, the plurality of R⁵ may be the same as or different from each other.]

(b)

b is preferably 0 or 1 from the viewpoint of achieving an appropriate oxidation-reduction potential.

The o-site of the hydroxy group is preferably a secondary or tertiary alkyl group, and more preferably a tertiary alkyl group, from the viewpoint of having a large steric hindrance, preventing a coupling reaction between phenoxy radicals generated after oxidation, and capable of functioning as an antioxidant again. The o-site of the hydroxy group is preferably a t-butyl group that is a minimum tertiary alkyl group, from the viewpoint that the t-butyl group is less likely to remain in the emission layer after film formation because the t-butyl group is inexpensive and has a small molecular weight. That is, the composition for an organic electroluminescent element according to the present invention preferably contains a compound represented by the following formula (1-2) as the compound represented by the formula (1-1).

### (Compound Represented by Formula (1-2))

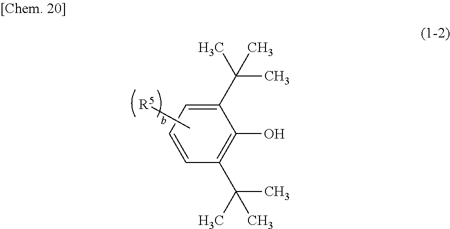

[in the above formula, b and R⁵ have the same meaning as b and R⁵ in the formula (1-1).]

As described above, b is preferably 0 or 1 from the viewpoint of achieving an appropriate oxidation-reduction potential.

### [Solvent]

The composition for an organic electroluminescent element according to the present invention contains alkylated naphthalene or diphenyl alkane as a first solvent, and an aromatic ether and/or an aromatic ester as a second solvent.

That is, the composition for an organic electroluminescent element according to the first aspect of the present invention contains alkylated naphthalene as a first solvent, and an aromatic ether and/or an aromatic ester as a second solvent.

In addition, the composition for an organic electroluminescent element according to the second aspect of the present invention contains diphenyl alkane as a first solvent, and an aromatic ether and/or an aromatic ester as a second solvent.

The solvent contained in the composition for an organic electroluminescent element according to the present invention is a volatile liquid component used for forming a layer containing a functional material by wet-process film formation. The solvent is preferably a solvent in which a luminescent material or a charge-transporting material as the functional material is satisfactorily dissolved.

### <First Solvent: Alkylated Naphthalene>

The alkylated naphthalene as an aspect of the first solvent may be monoalkylated naphthalene having one alkyl group, dialkylated naphthalene having two alkyl groups, or trialkylated naphthalene, tetraalkylated naphthalene, heptaalkylated naphthalene, hexaalkylated naphthalene, or the like having three or more alkyl groups.

From the viewpoint of low boiling point and high volatility, monoalkylated naphthalene or dialkylated naphthalene is preferable, and monoalkylated naphthalene is more preferable.

From the viewpoint of high melting point and low possibility of solidification when the composition is placed at a low temperature, dialkylated naphthalene and trialkylated naphthalene are preferable, and trialkylated naphthalene is more preferable.

From the viewpoint of appropriate boiling point and melting point, dialkylated naphthalene is preferable.

Monoalkylated naphthalene is represented by the following formula (4A).

### (Formula (4A))

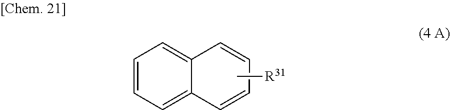

[In the above formula, R³¹ represents an alkyl group which may have a substituent.]

### (R³¹)

R³¹, which is an alkyl group substituted with naphthalene in the formula (4A), is preferably an alkyl group having 1 to 12 carbon atoms, and examples thereof include a methyl group, an ethyl group, a propyl group, an isopropyl group, a butyl group, an isobutyl group, an s-butyl group, a t-butyl group, a pentyl group, an isopentyl group, a hexyl group, a cyclohexyl group, a heptyl group, an octyl group, a 2-ethylhexyl group, a nonyl group, a decyl group, an undecyl group, and a dodecyl group. Among these, a methyl group, an ethyl group, a propyl group, and an isopropyl group are particularly preferable from the viewpoint that the boiling point is low and high volatility can be ensured. R³¹ may have a phenyl group as a substituent, and in this case, the alkyl group having a substituent is preferably a benzyl group or a 2-phenylethyl group.

Examples of the monoalkylated naphthalene include 1-methylnaphthalene, 2-methylnaphthalene, 1-ethylnaphthalene, 2-ethylnaphthalene, 1-propylnaphthalene, 2-propylnaphthalene, 1-isopropylnaphthalene, 2-isopropylnaphthalene, 1-butylnaphthalene, 2-butylnaphthalene, 1-cyclohexylnaphthalene, and 2-cyclohexylnaphthalene.

Dialkylated naphthalene is represented by the following formula (4A-1).

### (Formula (4A-1))

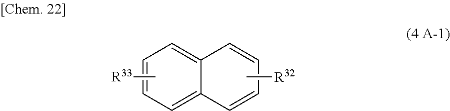

[In the above formula, R³² and R³³ represent alkyl groups which may have a substituent.]

(R³² and R³³)

Preferred examples of R³² and R³³ in the formula (4A-1) are the same as preferred examples of R³¹ in the formula (4A).

Examples of the dialkylated naphthalene include 1,2-dimethylnaphthalene, 1,3-dimethylnaphthalene, 1,4-dimethylnaphthalene, 1,5-dimethylnaphthalene, 1,6-dimethylnaphthalene, 1,7-dimethylnaphthalene, 1,8-dimethylnaphthalene, 1-methyl, 7-secondary butyl-1-methylnaphthalene, 7-(hexane-2-yl)-1-methylnaphthalene, 7-butyl-1-methylnaphthalene, 7-tertiary butyl-1-methylnaphthalene, and 2,7-diisopropylnaphthalene. Trialkylated naphthalene is represented by the following formula (4A-2).

### (Formula (4A-2))

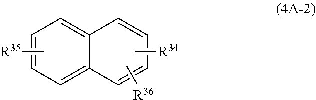

[In the above formula, R³⁴ to R³⁶ represent alkyl groups which may have a substituent.]

(R³⁴ to R³⁶)

Preferred examples of R³⁴ to R³⁶ in the formula (4A-2) are the same as the preferred examples of R³¹ in the formula (4A).

Examples of the trialkylated naphthalene include 1,2,3-trimethylnaphthalene, 1,2,4-trimethylnaphthalene, 1,2,5-trimethylnaphthalene, 1,2,6-trimethylnaphthalene, 1,2,7-trimethylnaphthalene, 1,2,8-trimethylnaphthalene, 1,2,3-triethylnaphthalene, and 1,2,7-triisopropylnaphthalene.

One type of these alkylated naphthalene as the first solvent may be used alone, or two or more types thereof may be used in any combination and ratio.

### <First Solvent: Diphenyl Alkane>

Diphenyl alkane, which is another aspect of the first solvent, may be diphenyl alkane having no substituent at phenyl group sites on both sides, (alkylated phenyl)phenylalkane having an alkyl group substituted at a phenyl group site on one side, or dialkylated diphenyl alkane having an alkyl group substituted at the phenyl group sites on both sides.

In general, a functional material forming an organic electroluminescent element is an aromatic compound. In the diphenyl alkane as the first solvent, two phenyl groups are bonded to one terminal carbon atom of the alkyl group. That is, two phenyl groups are linked by a methylene group. Here, the phenyl group interacts with an aromatic solute compound to dissolve the aromatic solute compound as the functional material at a high concentration. Further, it is presumed that, when two benzene rings are linked by a quaternary carbon atom, flatness of a molecular skeleton is broken, the degree of freedom is increased, the benzene rings are easily arranged freely so as to further improve affinity with the solute compound, and the solubility is further increased.

In the case of (alkylated phenyl)phenylalkane, it is considered that since only one of the two phenyl groups has a substituent, asymmetry is increased, an asymmetric aggregate is formed, the solute compound is more dispersed than a symmetric solvent, and a more uniform and flat amorphous organic film is formed.

The diphenyl alkane having no substituent at the phenyl group sites on both sides has a structure represented by the following formula (4B) and in which the alkyl group R³¹ is substituted in diphenylmethane. That is, the diphenyl alkane is preferably represented by the following formula (4B).

### (Formula (4B))

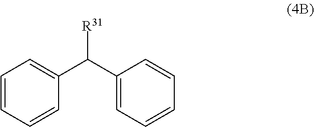

[In the above formula, R³¹ represents a hydrogen atom or an alkyl group.]

### (R³¹)

R³¹, which is an alkyl group substituted with diphenylmethane in the formula (4B), is preferably an alkyl group having 1 to 6 carbon atoms. The alkyl group may be a linear alkyl group or a branched alkyl group. For example, a methyl group, an ethyl group, a propyl group, a butyl group, a pentyl group, and a hexyl group can be used. A preferred range thereof includes a methyl group, an ethyl group, a linear or branched propyl group, a linear or branched butyl group, a linear or branched pentyl group, and a linear or branched hexyl group. Among these, a butyl group, a pentyl group, and a hexyl group are particularly preferable from the viewpoint that the boiling point is high and volatilization is less likely to occur under normal temperature and normal pressure.

Examples of the diphenyl alkane include diphenylmethane, 1,1-diphenylethane, 1,1-diphenylpropane, 1,1-diphenylbutane, 1,1-diphenylpentane, 1,1-diphenylhexane, 1,1-diphenylheptane, 5-methyl-1,1-diphenylhexane, 4-methyl-1,1-diphenylhexane, 3-methyl-1,1-diphenylhexane, and 2-methyl-1,1-diphenylhexane.

The (alkylated phenyl)phenylalkane is represented by the following formula (4B-1).

### (Formula (4B-1))

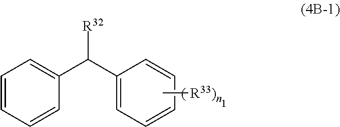

[In the above formula, R³² represents a hydrogen atom or an alkyl group, R³³ represents an alkyl group, and n₁ represents an integer of 1 to 5.]

(R³², R³³, and n₁)

Preferred examples of R³² in the formula (4B-1) are the same as preferred examples of R³¹ in the formula (4B). R³³ substituted with the diphenyl alkane in the formula (4B-1) are each independently preferably an alkyl group having 1 to 3 carbon atoms, and particularly preferably a methyl group, an ethyl group, or a propyl group from the viewpoint of appropriate melting point and boiling point. In the formula (4B-1), n₁ is an integer of 1 to 5.

In the formula (4B-1), regarding preferred ranges of R³² and R³³ for n₁, when n₁ is 1, R³² is preferably hydrogen, a methyl group, an ethyl group, a propyl group, or an isopropyl group, and R³³ is preferably a methyl group or an ethyl group, and particularly preferably R³² is hydrogen and R³³ is a methyl group from the viewpoint of appropriate melting point and boiling point.

Examples of the (alkylated phenyl)phenylalkane include 1-benzyl-4-methylbenzene, 1-benzyl-4-ethylbenzene, 1-benzyl-4-propylbenzene, 2,4-dimethyl-1-(1-phenylethyl)benzene, and 2,4-diethyl-1-(1-phenylethyl)benzene.

The dialkylated diphenyl alkane is represented by the following formula (4B-2).

### (Formula (4B-2))

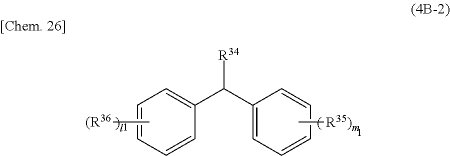

[In the above formula, R³⁴ represents a hydrogen atom or an alkyl group, R³⁵ and R³⁶ represent alkyl groups, and m¹ and l¹ represent integers of 1 to 5.]

(R³⁴ to R³⁶)

Preferred examples of R³⁴ in the formula (4B-2) are the same as the preferred examples of R³¹ in the formula (4B). Preferred examples of R³⁵ and R³⁶ in the formula (4B-2) are the same as preferred examples of R³³ in the formula (4B-1).

Examples of the dialkylated diphenyl alkane include 4,4′-dimethyl diphenylmethane, 4,4′-dimethyl diphenylethane, 4,4′-dimethyl diphenylpropane, 4,4′-dimethyl diphenylbutane, 4,4′-dimethyl diphenylpentane, 4,4′-dimethyl diphenylmethane, 3, 4′-dimethyl diphenylmethane, 2,3′-dimethyl diphenylmethane, 2,4′-dimethyl diphenylmethane, 2,3,3′-trimethyl diphenylmethane, and 2,3,2′,3′-tetramethyl diphenylmethane.

One type of these diphenyl alkane as the first solvent may be used alone, or two or more types thereof may be used in any combination and ratio.

In addition, one or more types of the alkylated naphthalene as the first solvent and one or more types of the diphenyl alkane as the first solvent may be used in any combination and ratio.

### <Second Solvent>

The composition for an organic electroluminescent element according to the present invention contains an aromatic ether and/or an aromatic ester as the second solvent.

The second solvent is preferably an aromatic ether from the viewpoint of higher compatibility with the alkylated naphthalene or diphenyl alkane as the first solvent.

The aromatic ether is preferably an alkoxy benzene which may have an alkyl group represented by the following formula (5) from the viewpoint of having high solubility.

### (Formula (5) Aromatic Ether)

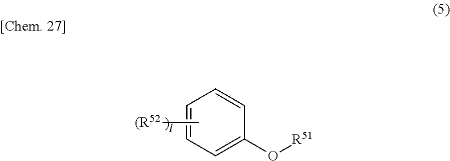

[In the above formula, i represents an integer of 0 to 5; and R⁵¹ and R⁵² represent alkyl groups which may have a substituent.]

i is preferably an integer of 0 to 3, and still more preferably 0 or 1, from the viewpoint of low boiling point and high volatility.

R⁵¹ and R⁵² are preferably alkyl groups having 1 to 12 carbon atoms, and examples thereof include a methyl group, an ethyl group, a propyl group, an isopropyl group, a butyl group, an isobutyl group, an s-butyl group, a t-butyl group, a pentyl group, an isopentyl group, a hexyl group, a cyclohexyl group, a heptyl group, an octyl group, a 2-ethylhexyl group, a nonyl group, a decyl group, an undecyl group, and a dodecyl group. R⁵¹ and R⁵² may have a phenyl group as a substituent, and in this case, the alkyl group having a substituent is preferably a benzyl group or a 2-phenylethyl group.

The aromatic ether is preferably a phenoxybenzene which may have an alkyl group represented by the following formula (5-1) from the viewpoint of having a high boiling point and being suitable for large-area coating.

### (Formula (5-1))

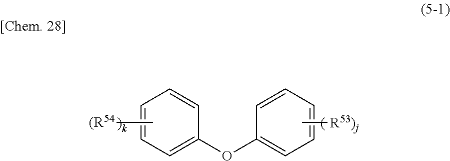

[In the above formula, j and k represent integers of 0 to 5; and R⁵³ and R⁵⁴ represent alkyl groups which may have a substituent.]

j and k are preferably integers of 0 to 2, and still more preferably 0 or 1, from the viewpoint of low boiling point and high volatility.

R⁵³ and R⁵⁴ are preferably alkyl groups having 1 to 12 carbon atoms, and examples thereof include a methyl group, an ethyl group, a propyl group, an isopropyl group, a butyl group, an isobutyl group, an s-butyl group, a t-butyl group, a pentyl group, an isopentyl group, a hexyl group, a cyclohexyl group, a heptyl group, an octyl group, a 2-ethylhexyl group, a nonyl group, a decyl group, an undecyl group, and a dodecyl group. R⁵³ and R⁵⁴ may have a phenyl group as a substituent, and in this case, the alkyl group having a substituent is preferably a benzyl group or a 2-phenylethyl group.

The second solvent is preferably an aromatic ester from the viewpoint of having higher polarity and being expectable to further prevent a change in liquid physical properties.

The aromatic ester is preferably an ester benzoate which may have an alkyl group represented by the following formula (6).

### (Formula (6) Aromatic Ester)

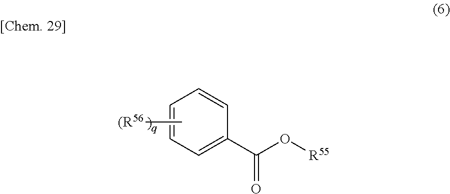

[In the above formula, q represents an integer of 0 to 5; and R⁵⁵ and R⁵⁶ represent alkyl groups which may have a substituent.]

q is preferably an integer of 0 to 2, and still more preferably 0 or 1, from the viewpoint of low boiling point and high volatility.

R⁵⁵ and R⁵⁶ are preferably alkyl groups having 1 to 12 carbon atoms, and examples thereof include a methyl group, an ethyl group, a propyl group, an isopropyl group, a butyl group, an isobutyl group, an s-butyl group, a t-butyl group, a pentyl group, an isopentyl group, a hexyl group, a cyclohexyl group, a heptyl group, an octyl group, a 2-ethylhexyl group, a nonyl group, a decyl group, an undecyl group, and a dodecyl group. R⁵⁵ and R⁵⁶ may have a phenyl group as a substituent, and in this case, the alkyl group having a substituent is preferably a benzyl group or a 2-phenylethyl group.

One type of these aromatic ether and/or aromatic ester as the second solvent may be used alone, or two or more types thereof may be used in any combination and ratio. That is, only one type of aromatic ether may be used, only one type of aromatic ester may be used, or one or two or more types of aromatic ethers and one or two or more types of aromatic esters may be used in any combination and ratio.

### <Other Solvents>

The composition for an organic electroluminescent element according to the present invention may contain solvents other than the solvents exemplified as the first solvent and the second solvent.

Preferred examples of the other solvents include: alkanes such as n-decane, cyclohexane, ethylcyclohexane, decalin, and bicyclohexane; aromatic hydrocarbons such as toluene, xylene, mesitylene, cyclohexylbenzene (phenylcyclohexane), and tetralin; halogenated aromatic hydrocarbons such as chlorobenzene, dichlorobenzene, and trichlorobenzene; alicyclic ketones such as cyclohexanone, cyclooctanone, and fenchone; alicyclic alcohols such as cyclohexanol and cyclooctanol; aliphatic ketones such as methyl ethyl ketone and dibutyl ketone; aliphatic alcohols such as butanol and hexanol; and aliphatic ethers such as ethylene glycol dimethyl ether, ethylene glycol diethyl ether, and propylene glycol-1-monomethyl ether acetate (PGMEA).

One type of the other solvents may be used alone, or two or more types thereof may be used in any combination and ratio.

### <Boiling Point of Solvent>

The boiling point of the solvent is generally 80° C. or higher, preferably 100° C. or higher, more preferably 150° C. or higher, particularly preferably 200° C. or higher, and is generally 350° C. or lower, preferably 320° C. or lower, more preferably 300° C. or lower. When the boiling point is lower than this range, there is a possibility that film formation stability is reduced due to solvent evaporation from the composition during wet-process film formation.

### [Content of Each Component]

In a case where the composition for an organic electroluminescent element according to the present invention contains a luminescent material as the functional material, a content (concentration) of the luminescent material in the composition for an organic electroluminescent element according to the present invention is preferably 0.05 mass % or more, more preferably 0.1 mass % or more, still more preferably 0.2 mass % or more, and is preferably 8.0 mass % or less, more preferably 4.0 mass % or less, still more preferably 2.0 mass % or less.

When the concentration of the luminescent material is equal to or greater than the above lower limit, a layer containing the luminescent material in a sufficient amount can be formed, and when the concentration is equal to or less than the above upper limit, a uniform state can be easily maintained without precipitation of the dissolved luminescent material.

In a case where the composition for an organic electroluminescent element according to the present invention contains a charge-transporting material as the functional material, a content (concentration) of the charge-transporting material in the composition for an organic electroluminescent element according to the present invention is preferably 0.1 mass % or more, more preferably 0.2 mass % or more, still more preferably 0.4 mass % or more, and is preferably 16 mass % or less, more preferably 8.0 mass % or less, still more preferably 4.0 mass % or less.

When the concentration of the charge-transporting material is equal to or greater than the above lower limit, a layer containing the charge-transporting material in a sufficient amount can be formed, and when the concentration is equal to or less than the above upper limit, a uniform state can be easily maintained without precipitation of the dissolved charge-transporting material.

In a case where the composition for an organic electroluminescent element according to the present invention contains a luminescent material and a charge-transporting material as the functional material, a total content (concentration) of these materials in the composition for an organic electroluminescent element according to the present invention is preferably 0.1 mass % or more, more preferably 0.2 mass % or more, still more preferably 0.4 mass % or more, and is preferably 16 mass % or less, more preferably 8.0 mass % or less, still more preferably 4.0 mass % or less.

When the total concentration of the functional materials is equal to or greater than the above lower limit, a layer containing the functional materials in a sufficient amount can be formed, and when the concentration is equal to or less than the above upper limit, a uniform state can be easily maintained without precipitation of the dissolved functional materials.

In addition, a mass ratio of the content of the luminescent material to the content of the charge-transporting material is preferably in a range of 1:0.8 to 16, more preferably in a range of 1:1.2 to 8.0, and particularly preferably in a range of 1:1.6 to 4.0. When the mass ratio of the content of the luminescent material to the content of the charge-transporting material is within the above range, an organic electroluminescent element having a low driving voltage and high emission efficiency can be produced.

A content (concentration) of the phenol derivative as the compound represented by the formula (1) contained in the composition for an organic electroluminescent element according to the present invention is preferably 5 mass ppm or more, more preferably 10 mass ppm or more, still more preferably 20 mass ppm or more, and is preferably 4,000 mass ppm or less, more preferably 2,000 mass ppm or less, still more preferably 1,000 mass ppm or less. When the concentration of the phenol derivative is equal to or greater than the above lower limit, an effect of preventing deterioration of the functional material by the phenol derivative can be sufficiently obtained, and when the concentration is equal to or less than the above upper limit, the phenol derivative and an oxide thereof can be easily removed together with the solvent when forming the emission layer.

A content of the alkylated naphthalene or diphenyl alkane as the first solvent contained in the composition for an organic electroluminescent element according to the present invention is preferably 2.0 mass % or more, more preferably 5.0 mass % or more, still more preferably 10 mass % or more, and is preferably 95 mass % or less, more preferably 90 mass % or less, still more preferably 80 mass % or less. When the content of the first solvent is equal to or greater than the above lower limit, volatilization of the solvent when applied to a large area can be controlled, and when the content is equal to or less than the above upper limit, a second solvent which can reduce a change in liquid physical properties when ink is stored for a long period of time can be sufficiently added.

A content of the aromatic ether and/or the aromatic ester as the second solvent contained in the composition for an organic electroluminescent element according to the present invention is preferably 2.0 mass % or more, more preferably 5.0 mass % or more, still more preferably 10 mass % or more, and is preferably 95 mass % or less, more preferably 90 mass % or less, still more preferably 80 mass % or less. When the content of the second solvent is equal to or greater than the above lower limit, a change in liquid physical properties when ink is stored for a long period of time can be reduced, and when the content is equal to or less than the above upper limit, the first solvent enabling to control volatilization of the solvent when applied to a large area can be sufficiently added.

In addition, regarding a mass ratio of the first solvent to the second solvent contained in the composition for an organic electroluminescent element according to the present invention, it is preferable that first solvent:second solvent=1:0.02 to 20, more preferable that first solvent:second solvent=1:0.04 to 10, and still more preferable that first solvent:second solvent=1:0.1 to 5. When the mass ratio of the second solvent to the first solvent is equal to or greater than the above lower limit, a change in liquid physical properties when ink is stored for a long period of time can be reduced, and when the mass ratio is equal to or less than the above upper limit, the first solvent enabling to control volatilization of the solvent when applied to a large area can be sufficiently added.

The composition for an organic electroluminescent element according to the present invention may further contain the above-described other solvents in addition to the above first solvent and second solvent, and in a case where the composition for an organic electroluminescent element according to the present invention contains the other solvents, in order to more effectively obtain the effect of the present invention by using the first solvent and the second solvent, a content of the other solvents in the total solvent is preferably 80 mass % or less, particularly preferably 40 mass % or less, and the composition for an organic electroluminescent element according to the present invention most preferably does not contain the other solvents.

In addition, a total content of the solvents in the composition for an organic electroluminescent element according to the present invention is preferably large from the viewpoint of easily executing a film formation work due to its low viscosity, and meanwhile, is preferably small from the viewpoint of easily forming a thick film. The total content of the solvents in the composition for an organic electroluminescent element according to the present invention is preferably 1 mass % or more, more preferably 10 mass % or more, particularly preferably 50 mass % or more, and is preferably 99.99 mass % or less, more preferably 99.9 mass % or less, particularly preferably 99 mass % or less.

### [Use]

The composition for an organic electroluminescent element according to the present invention is particularly preferably used as a composition for forming an emission layer containing a luminescent material and a charge-transporting material as functional materials.

### [Organic Electroluminescent Element]

The organic electroluminescent element according to the present invention includes an emission layer formed using the composition for an organic electroluminescent element according to the present invention.

The organic electroluminescent element according to the present invention preferably includes a substrate and, disposed thereon, at least an anode, a cathode, and at least one organic layer between the anode and the cathode, and at least one of the organic layers is an emission layer formed by a wet-process film formation method using the composition for an organic electroluminescent element according to the present invention.

That is, the present invention also relates to a method for producing an organic electroluminescent element, including a step of forming an emission layer by a wet-process film formation method using the composition for an organic electroluminescent element according to the present invention.

In the present invention, the wet-process film formation method refers to a method adopts, as a film forming method, that is, a coating method, a method for forming a film by a wet process such as spin coating, dip coating, die coating, bar coating, blade coating, roll coating, spray coating, capillary coating, an inkjet method, nozzle printing, screen printing, gravure printing, or flexographic printing, and a film formed by these methods is dried to form a film.

The FIGURE is a schematic cross-sectional view which shows an example of a preferred structure of an organic electroluminescent element 10 according to the present invention, and in the FIGURE, numeral 1 denotes a substrate, numeral 2 denotes an anode, numeral 3 denotes a hole injection layer, numeral 4 denotes a hole transport layer, numeral 5 denotes an emission layer, numeral 6 denotes a hole blocking layer, numeral 7 denotes an electron transport layer, numeral 8 denotes an electron injection layer, and numeral 9 denotes a cathode.

As materials to be applied to these structures, known materials can be applied. Although the materials are not particularly limited, representative materials and methods for formation with respect to each layer are described below as examples. In a case where a patent document, a paper, or the like has been cited, the contents thereof can be suitably applied or used within the range of common knowledge for persons skilled in the art.

### [Substrate 1]

The substrate 1 serves as a support of the organic electroluminescent element, and is generally made of a plate of quartz or glass, a metal sheet, a metal foil, a plastic film or sheet, or the like. Among these, a glass plate and a plate of a transparent synthetic resin such as polyester, polymethacrylate, polycarbonate, and polysulfone are preferable. The substrate 1 is preferably formed of a material having a high gas barrier property because deterioration of the organic electroluminescent element due to outside air is less likely to occur. Therefore, particularly in a case where a material having a low gas barrier property, such as a synthetic resin substrate, is used, it is preferable to provide a dense silicon oxide film or the like on at least one surface of the substrate 1 to improve the gas barrier property.

### [Anode 2]

The anode 2 has a function of injecting holes into a layer on an emission layer side.

The anode 2 is generally formed of a metal such as aluminum, gold, silver, nickel, palladium, or platinum; a metal oxide such as an oxide of indium and/or tin; a metal halide such as copper iodide; a conductive polymer such as carbon black, poly(3-methylthiophene), polypyrrole, or polyaniline; or the like.

The anode 2 is frequently formed generally by a dry method such as a sputtering method, a vacuum deposition method, or the like. In a case where fine particles of a metal such as silver, fine particles of copper iodide or the like, carbon black, fine particles of a conductive metal oxide, fine powder of a conductive polymer, or the like is used to form the anode 2, the anode 2 can also be formed by dispersing the particles or powder in an appropriate binder resin solution and applying the solution on the substrate. Further, in the case of a conductive polymer, a thin film is directly formed on the substrate by electrolytic polymerization or the conductive polymer is applied on the substrate to form the anode 2 (Appl. Phys. Lett., Vol. 60, p. 2711, 1992).

The anode 2 generally has a single-layer structure, but may have a multilayer structure as appropriate. In a case where the anode 2 has a multilayer structure, a different conductive material may be laminated on an anode of a first layer.

A thickness of the anode 2 may be determined according to required transparency, material, and the like. In particular, in a case where high transparency is required, a thickness at which transmittance of visible light is 60% or more is preferable, and a thickness at which the transmittance of visible light is 80% or more is still more preferable. The thickness of the anode 2 is generally 5 nm or more, preferably 10 nm or more, and is generally 1,000 nm or less, preferably 500 nm or less. Meanwhile, in a case where the transparency is not required, the thickness of the anode 2 may be set to any thickness depending on a required strength or the like, and in this case, the thickness of the anode 2 may be the same as that of the substrate 1.

In a case where a film is formed on a surface of the anode 2, it is preferable to remove impurities on the anode and adjust an ionization potential thereof to improve the hole injection property by executing a treatment such as ultraviolet and ozone, oxygen plasma, or argon plasma before the film formation.

### [Hole Injection Layer 3]

A layer having a function of transporting holes from an anode 2 side to an emission layer 5 side is generally referred to as a hole injection and transport layer or a hole transport layer. In a case where there are two or more layers having the function of transporting holes from the anode 2 side to the emission layer 5 side, a layer closer to the anode 2 side may be referred to as the hole injection layer 3. The hole injection layer 3 is preferably used from the viewpoint of enhancing the function of transporting holes from the anode 2 side to the emission layer 5 side. In a case where the hole injection layer 3 is used, the hole injection layer 3 is generally formed on the anode 2.

A thickness of the hole injection layer 3 is generally 1 nm or more, preferably 5 nm or more, and is generally 1,000 nm or less, preferably 500 nm or less.

A method for forming the hole injection layer 3 may be a vacuum deposition method or a wet-process film formation method. From the viewpoint of excellent film formability, the hole injection layer 3 is preferably formed by the wet-process film formation method.

The hole injection layer 3 preferably contains a hole-transporting compound, and more preferably contains a hole-transporting compound and an electron-accepting compound. Further, the hole injection layer 3 preferably contains a cation radical compound, and particularly preferably contains a cation radical compound and a hole-transporting compound.

### (Hole-Transporting Compound)

A composition for forming a hole injection layer generally contains a hole-transporting compound serving as the hole injection layer 3. In addition, in the case of the wet-process film formation method, a solvent is generally further contained. The composition for forming a hole injection layer preferably has high hole transportability and can efficiently transport injected holes. Therefore, it is preferable that hole mobility is high, and impurities serving as traps are not easily generated at the time of production, use, or the like. In addition, it is preferable that stability is excellent, the ionization potential is small, and transparency to visible light is high. In particular, in a case where the hole injection layer 3 is in contact with the emission layer 5, it is preferable that the hole injection layer 3 does not quench luminescence from the emission layer 5 or forms an exciplex with the emission layer 5 so as not to reduce the emission efficiency.

The hole-transporting compound is preferably a compound having an ionization potential of 4.5 eV to 6.0 eV, from the viewpoint of a charge injection barrier from the anode 2 to the hole injection layer 3. Examples of the hole-transporting compound include an aromatic amine-based compound, a phthalocyanine-based compound, a porphyrin-based compound, an oligothiophene-based compound, a polythiophene-based compound, a benzylphenyl-based compound, a compound in which a tertiary amine is linked via a fluorene group, a hydrazone-based compound, a silazane-based compound, and a quinacridone-based compound.

Among the exemplified compounds described above, an aromatic amine-based compound is preferable, and an aromatic tertiary amine compound is particularly preferable, from the viewpoint of amorphous property and visible light transmittance. Here, the aromatic tertiary amine compound is a compound having an aromatic tertiary amine structure, and also includes a compound having a group derived from an aromatic tertiary amine.

A type of the aromatic tertiary amine compound is not particularly limited, but it is preferable to use a polymer compound having a weight average molecular weight of 1,000 or more and 1,000,000 or less (polymerization-type compound in which repeating units are continuous), from the viewpoint of easily obtaining uniform luminescence due to a surface smoothing effect.

Preferred examples of the aromatic tertiary amine polymer compound include a polymer compound having a repeating unit represented by the following formula (I).

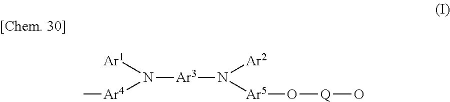

[In the above formula, Ar¹ and Ar² each independently represent an aromatic group which may have a substituent or a heteroaromatic group which may have a substituent; Ar³ to Ar⁵ each independently represent an aromatic group which may have a substituent or a heteroaromatic group which may have a substituent; Q represents a linking group selected from the group of linking groups shown below; and among Ar¹ to Ar⁵, two groups bonded to the same N atom may be bonded to each other to form a ring.]

The linking groups are shown below.

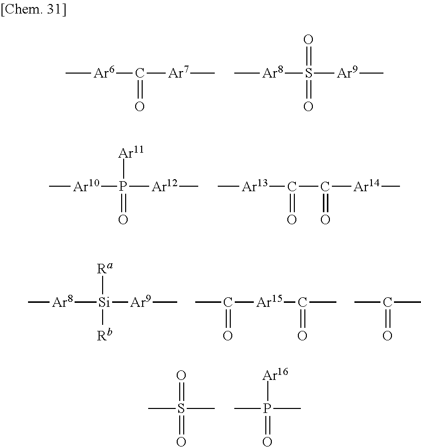

[In the above formulae, Ar⁶ to Ar¹⁶ each independently represent an aromatic group which may have a substituent or a heteroaromatic group which may have a substituent; and R^{a} and Rb each independently represent a hydrogen atom or any substituent.]

The aromatic group and the heteroaromatic group of Ar¹ to Ar¹⁶ are preferably a group derived from a benzene ring, a naphthalene ring, a phenanthrene ring, a thiophene ring, or a pyridine ring, and still more preferably a group derived from a benzene ring or a naphthalene ring, from the viewpoint of solubility, heat resistance, and hole injection and transport properties of the polymer compound.

Specific examples of the aromatic tertiary amine polymer compound having a repeating unit represented by the formula (I) include those disclosed in WO2005-089024.

### (Electron-Accepting Compound)

The hole injection layer 3 preferably contains an electron-accepting compound because conductivity of the hole injection layer 3 can be improved by oxidation of the hole-transporting compound.

As the electron-accepting compound, a compound having an oxidizing power and an ability to accept one electron from the hole-transporting compound described above is preferable, and specifically, a compound having an electron affinity of 4 eV or more is preferable, and a compound having an electron affinity of 5 eV or more is still more preferable.

Examples of such an electron-accepting compound include one or more compounds selected from the group consisting of a triaryl boron compound, a metal halide, a Lewis acid, an organic acid, an onium salt, a salt of an arylamine and a metal halide, and a salt of an arylamine and a Lewis acid. Specific examples thereof include onium salts substituted with an organic group, such as 4-isopropyl-4′-methyldiphenyliodonium tetrakis(pentafluorophenyl) borate and triphenylsulfonium tetrafluoroborate (WO2005-089024); high-valence inorganic compounds, such as iron (III) chloride (Japanese Patent Laid-Open No. H11-251067) and ammonium peroxodisulfate; cyano compounds, such as tetracyanoethylene; aromatic boron compounds, such as tris(pentafluorophenyl) borane (JP2003-31365A); fullerene derivatives; and iodine.

### (Cation Radical Compound)

The cation radical compound is preferably an ion compound formed of a cation radical and a counter anion, the cation radical being a chemical species with one electron removed from a hole-transporting compound. However, in a case where the cation radical is derived from a hole-transporting polymer compound, the cation radical has a structure in which one electron is removed from a repeating unit of the polymer compound.

The cation radical is preferably a chemical species with one electron removed from the compound described above as the hole-transporting compound. A chemical species with one electron removed from a preferred compound as the hole-transporting compound is preferable from the viewpoint of amorphous property, transmittance of visible light, heat resistance, solubility, and the like.

Here, the cation radical compound can be generated by mixing the above-described hole-transporting compound and electron-accepting compound. That is, when the above-described hole-transporting compound and electron-accepting compound are mixed, electron transfer occurs from the hole-transporting compound to the electron-accepting compound, and a cation ion compound formed of a cation radical and a counter anion of the hole-transporting compound is generated.

A cation radical compound derived from a polymer compound such as PEDOT/PSS (Adv. Mater., 2000, Vol. 12, p. 481) and emeraldine hydrochloride (J. Phys. Chem., 1990, Vol. 94, p. 7716) is also generated by oxidative polymerization (dehydrogenation polymerization).

The oxidative polymerization referred to herein is a method in which a monomer is chemically or electrochemically oxidized in an acidic solution by using a peroxodisulfate or the like. In the case of this oxidative polymerization (dehydrogenation polymerization), a cation radical with one electron removed from a repeating unit of a polymer, which is polymerized by oxidizing a monomer and has an anion derived from an acidic solution as a counter anion, is generated.

### (Formation of Hole Injection Layer 3 by Wet-Process Film Formation Method)

In a case where the hole injection layer 3 is formed by the wet-process film formation method, the hole injection layer 3 is generally formed by mixing a material serving as the hole injection layer 3 with a solvent capable of dissolving the material (solvent for hole injection layer) to prepare a composition for film formation (composition for forming hole injection layer), forming a film of the composition for forming a hole injection layer on a layer (generally, anode 2) corresponding to a lower layer of the hole injection layer 3 by the wet-process film formation method, and drying the film. Drying of the formed film can be executed in the same manner as a drying method in formation of the emission layer 5 by the wet-process film formation method, which is to be described later.

A concentration of the hole-transporting compound in the composition for forming a hole injection layer is any as long as the effect of the present invention is not significantly impaired, but a lower concentration is preferable from the viewpoint of thickness uniformity, while a higher concentration is preferable from the viewpoint of preventing defects from generating in the hole injection layer 3. Specifically, the concentration is preferably 0.01 mass % or more, still more preferably 0.1 mass % or more, particularly preferably 0.5 mass % or more, and meanwhile, is preferably 70 mass % or less, still more preferably 60 mass % or less, particularly preferably 50 mass % or less.

Examples of the solvent include an ether-based solvent, an ester-based solvent, an aromatic hydrocarbon-based solvent, and an amide-based solvent.

Examples of the ether-based solvent include aliphatic ethers such as ethylene glycol dimethyl ether, ethylene glycol diethyl ether, and propylene glycol-1-monomethyl ether acetate (PGMEA), and aromatic ethers such as 1,2-dimethoxybenzene, 1,3-dimethoxybenzene, anisole, phenetole, 2-methoxytoluene, 3-methoxytoluene, 4-methoxytoluene, 2,3-dimethylanisole, and 2,4-dimethylanisole.

Examples of the ester-based solvent include aromatic esters such as phenyl acetate, phenyl propionate, methyl benzoate, ethyl benzoate, propyl benzoate, and n-butyl benzoate.

Examples of the aromatic hydrocarbon-based solvent include toluene, xylene, cyclohexylbenzene, 3-isopropylbiphenyl, 1,2,3,4-tetramethylbenzene, 1,4-diisopropylbenzene, and methylnaphthalene.

Examples of the amide-based solvent include N,N-dimethylformamide and N,N-dimethylacetamide.

In addition to these, dimethyl sulfoxide or the like can also be used.

The formation of the hole injection layer 3 by the wet-process film formation method is generally executed by, preparing a composition for forming a hole injection layer, then applying the composition to the layer corresponding to the lower layer of the hole injection layer 3 (generally, anode 2) to form a film, and drying the film. In the hole injection layer 3, a coating film is generally dried by heating, vacuum drying, or the like after the film formation.

### (Formation of Hole Injection Layer 3 by Vacuum Deposition Method)

In the case where the hole injection layer 3 is formed by the vacuum deposition method, generally, one type or two or more types of constituent materials (the above-described hole-transporting compound, electron-accepting compound, and the like) of the hole injection layer 3 are put into a crucible disposed in a vacuum container (in a case where two or more types of materials are used, generally each type thereof is put into a separate crucible), the inside of the vacuum container is evacuated to about 10-+Pa by a vacuum pump, and then the crucible is heated (in the case where two or more types of materials are used, generally each crucible is heated) to evaporate the material while controlling an evaporation amount of the material in the crucible (in the case where two or more types of materials are used, generally each type thereof is evaporated while controlling the evaporation amount independently), and thereby forming the hole injection layer 3 on the anode 2 of a substrate placed so as to face the crucible. In the case where two or more types of materials are used, a mixture of these materials can be put in a crucible, heated, and vaporized to form the hole injection layer 3.

A degree of vacuum during the deposition is not limited as long as the effect of the present invention is not significantly impaired, but is generally 0.1×10⁻⁶ Torr (0.13×10⁻⁴ Pa) or higher and 9.0×10⁻⁶ Torr (12.0×10-+Pa) or lower. A rate of deposition is not limited as long as the effect of the present invention is not significantly impaired, but is generally 0.1 Å/sec or higher and 5.0 Å/sec or lower. A film formation temperature during the deposition is not limited as long as the effect of the present invention is not significantly impaired, but is preferably 10° C. or higher and 50° C. or lower.

### [Hole Transport Layer 4]

The hole transport layer 4 is a layer having a function of transporting holes from the anode 2 side to the emission layer 5 side. Although the hole transport layer 4 is not an essential layer in the organic electroluminescent element according to the present invention, this layer is preferably provided from the viewpoint of enhancing the function of transporting holes from the anode 2 to the emission layer 5. In a case where the hole transport layer 4 is provided, the hole transport layer 4 is generally formed between the anode 2 and the emission layer 5. In addition, in a case where the hole injection layer 3 described above is provided, the hole transport layer 4 is formed between the hole injection layer 3 and the emission layer 5.

A thickness of the hole transport layer 4 is generally 5 nm or more, preferably 10 nm or more, and meanwhile, is generally 300 nm or less, preferably 100 nm or less.

A method for forming the hole transport layer 4 may be a vacuum deposition method or a wet-process film formation method. From the viewpoint of excellent film formability, the hole transport layer 4 is preferably formed by the wet-process film formation method.

The hole transport layer 4 generally contains a hole-transporting compound serving as the hole transport layer 4. Examples of the hole-transporting compound contained in the hole transport layer 4 include aromatic diamines containing two or more tertiary amines and having two or more condensed aromatic rings substituted with nitrogen atoms, represented by 4,4′-bis[N-(1-naphthyl)-N-phenylamino]biphenyl (Japanese Patent Laid-Open No. H5-234681), aromatic amine-based compounds having a star burst structure, such as 4,4′,4″-tris(1-naphthylphenylamino)triphenylamine (J. Lumin., Vol. 72-74, p. 985, 1997), aromatic amine-based compounds formed of tetramers of triphenylamine (Chem. Commun., p. 2175, 1996), spiro compounds such as 2,2′, 7,7′-tetrakis-(diphenylamino)-9,9′-spirobifluorene (Synth. Metals, Vol. 91, p. 209, 1997), and carbazole derivatives such as 4,4′-N,N′-dicarbazole biphenyl. In addition, for example, polyvinyl carbazole, polyvinyl triphenylamine (Japanese Patent Laid-Open No. H7-53953), polyarylene ether sulfone containing tetraphenylbenzidine (Polym. Adv. Tech., Vol. 7, p. 33, 1996) can also be preferably used.

### (Formation of Hole Transport Layer 4 by Wet-Process Film Formation Method)

In the case where the hole transport layer 4 is formed by the wet-process film formation method, the hole transport layer 4 is generally formed using a composition for forming a hole transport layer instead of the composition for forming a hole injection layer in the same manner as in the case where the hole injection layer 3 is formed by the wet-process film formation method described above.

In the case where the hole transport layer 4 is formed by the wet-process film formation method, the composition for forming a hole transport layer generally further contains a solvent. The solvent used in the composition for forming a hole transport layer may be the same as the solvent used in the composition for forming a hole injection layer described above.

A concentration of the hole-transporting compound in the composition for forming a hole transport layer may be in the same range as the concentration of the hole-transporting compound in the composition for forming a hole injection layer.

### (Formation of Hole Transport Layer 4 by Vacuum Deposition Method)

Also in the case where the hole transport layer 4 is formed by the vacuum deposition method, the hole transport layer 4 can be generally formed by using a constituent material of the hole transport layer 4 instead of the constituent material of the hole injection layer 3 in the same manner as in the case where the hole injection layer 3 is formed by the vacuum deposition method described above. Film formation conditions such as a degree of vacuum, a rate of deposition, and a temperature at the time of the deposition can be the same as those at the time of vacuum deposition of the hole injection layer 3.

### [Emission Layer 5]

The emission layer 5 is a layer having a function of emitting light by being excited by recombination of holes injected from the anode 2 and electrons injected from the cathode 9 when an electric field is applied between a pair of electrodes. The emission layer 5 is a layer formed between the anode 2 and the cathode 9. The emission layer 5 is formed between the hole injection layer 3 and the cathode 9 in a case where the hole injection layer 3 is present on the anode 2, and is formed between the hole transport layer 4 and the cathode 9 in a case where the hole transport layer 4 is present on the anode 2.

A thickness of the emission layer 5 is any as long as the effect of the present invention is not significantly impaired, but a thick layer is preferable from the viewpoint that defects are less likely to occur in the film, and meanwhile, a thin layer is preferable from the viewpoint that a low driving voltage is likely to be obtained. Therefore, the thickness of the emission layer 5 is preferably 3 nm or more, still more preferably 5 nm or more, and meanwhile, is generally preferably 200 nm or less, still more preferably 100 nm or less.

The emission layer 5 contains at least a material having a luminescence property (luminescent material), and preferably contains a material having a charge transporting property (charge-transporting material).

A general luminescent material and a method for forming an emission layer will be described below, but in the organic electroluminescent element according to the present invention, the emission layer is preferably formed by the wet-process film formation method using the above-described composition for an organic electroluminescent element according to the present invention.

In addition, as the luminescent material, an iridium complex which is an organometallic complex having iridium as a central element is preferable, but other luminescent materials may be appropriately used.

Hereinafter, luminescent materials other than the iridium complex compound will be described in detail.

### (Luminescent Material)

The luminescent material emits light at a desired emission wavelength, and is not particularly limited as long as the effect of the present invention is not impaired, and a known luminescent material can be applied. The luminescent material may be a fluorescent material or a phosphorescent material, but a material having favorable emission efficiency is preferable, and a phosphorescent material is preferable from the viewpoint of internal quantum efficiency.

Examples of the fluorescent material include the following materials.

Examples of a fluorescent material that emits blue light (blue fluorescent material) include naphthalene, perylene, pyrene, anthracene, coumarin, chrysene, p-bis(2-phenylethenyl)benzene, and derivatives thereof.

Examples of a fluorescent material that emits green light (green fluorescent material) include quinacridone derivatives, coumarin derivatives, and aluminum complexes such as Al(C₉H₆NO)₃.

Examples of a fluorescent material that emits yellow light (yellow fluorescent material) include rubrene and perimidone derivatives.

Examples of a fluorescent material that emits red light (red fluorescent material) include 4-(dicyanomethylene)-2-methyl-6-(p-dimethylaminostyryl)-4H-pyran-based (DCM-based) compounds, benzopyran derivatives, rhodamine derivatives, benzothioxanthene derivatives, and azabenzothioxanthene.

Examples of the phosphorescent material include organometallic complexes containing a metal selected from Groups 7 to 11 of a long-period periodic table (hereinafter, the term “periodic table” refers to a long-period periodic table unless otherwise specified). Preferred examples of the metal selected from Groups 7 to 11 of the periodic table include ruthenium, rhodium, palladium, silver, rhenium, osmium, iridium, platinum, and gold.

A ligand of the organometallic complex is preferably a ligand in which a (hetero) aryl group is linked to pyridine, pyrazole, phenanthroline, or the like, such as a (hetero) arylpyridine ligand, or a (hetero) arylpyrazole ligand, and particularly preferably a phenylpyridine ligand or a phenylpyrazole ligand. Here, (hetero) aryl represents an aryl group or a heteroaryl group.

Specific examples of preferred phosphorescent materials include phenylpyridine complexes such as tris(2-phenylpyridine) iridium, tris(2-phenylpyridine) ruthenium, tris(2-phenylpyridine) palladium, bis(2-phenylpyridine) platinum, tris(2-phenylpyridine) osmium, and tris(2-phenylpyridine) rhenium, and porphyrin complexes such as octaethyl platinum porphyrin, octaphenyl platinum porphyrin, octaethyl palladium porphyrin, and octaphenyl palladium porphyrin.

Examples of polymer-based luminescent materials include polyfluorene-based materials such as poly(9,9-dioctylfluorene-2,7-diyl), poly[(9,9-dioctylfluorene-2,7-diyl)-co-(4,4′-(N-(4-sec-butylphenyl))diphenylamine)], and poly[(9,9-dioctylfluorene-2,7-diyl)-co-(1,4-benzo-2 {2,1′-3}-triazole)], and polyphenylene vinylene-based materials such as poly[2-methoxy-5-(2-ethylhexyloxy)-1,4-phenylenevinylene].

### (Charge-Transporting Material)

The charge-transporting material is a material having a positive charge (hole) transporting property or a negative charge (electron) transporting property, and is not particularly limited as long as the effect of the present invention is not impaired, and a known material can be applied.

As the charge-transporting material, a compound or the like commonly used for the emission layer 5 of an organic electroluminescent element can be used, and in particular, a compound used as a host material of the emission layer 5 is preferable.

Specific examples of the charge-transporting material include compounds exemplified as hole-transporting compounds of the hole injection layer 3, such as an aromatic amine-based compound, a phthalocyanine-based compound, a porphyrin-based compound, an oligothiophene-based compound, a polythiophene-based compound, a benzylphenyl-based compound, a compound in which a tertiary amine is linked via a fluorene group, a hydrazone-based compound, a silazane-based compound, a silanamine-based compound, a phosphamine-based compound, and a quinacridone-based compound, and include an electron-transporting compound such as an anthracene-based compound, a pyrene-based compound, a carbazole-based compound, a pyridine-based compound, a phenanthroline-based compound, an oxadiazole-based compound, and a silole-based compound.

In addition, for example, compounds exemplified as hole-transporting compounds of the hole transport layer 4 can also be preferably used, such as aromatic diamines containing two or more tertiary amines and having two or more condensed aromatic rings substituted with nitrogen atoms, represented by 4,4′-bis[N-(1-naphthyl)-N-phenylamino]biphenyl (Japanese Patent Laid-Open No. H5-234681), aromatic amine-based compounds having a star burst structure, such as 4,4′,4″-tris(1-naphthylphenylamino)triphenylamine (J. Lumin., Vol. 72-74, p. 985, 1997), aromatic amine-based compounds formed of tetramers of triphenylamine (Chem. Commun., p. 2175, 1996), fluorene-based compounds such as 2,2′,7,7′-tetrakis-(diphenylamino)-9,9′-spirobifluorene (Synth. Metals, Vol. 91, p. 209, 1997), and carbazole-based compounds such as 4,4′-N,N′-dicarbazole biphenyl. Other examples thereof include oxadiazole-based compounds such as 2-(4-biphenylyl)-5-(p-tert-butylphenyl)-1,3,4-oxadiazole (tBu-PBD) and 2,5-bis(1-naphthyl)-1,3,4-oxadiazole (BND), silole-based compounds such as 2,5-bis(6′-(2′,2″-bipyridyl))-1,1-dimethyl-3,4-diphenylsilole (PyPySPyPy), and phenanthroline-based compounds such as bathophenanthroline (BPhen) and 2,9-dimethyl-4,7-diphenyl-1,10-phenanthroline (BCP, bathocuproine).

### (Formation of Emission Layer 5 by Wet-Process Film Formation Method)

The method for forming the emission layer 5 may be a vacuum deposition method or a wet-process film formation method, but the wet-process film formation method is preferable because of excellent film formability.

In the case where the emission layer 5 is formed by the wet-process film formation method, the emission layer 5 is generally formed by using a composition for forming an emission layer prepared by mixing a material serving as the emission layer 5 with a solvent capable of dissolving the material (solvent for emission layer) instead of the composition for forming a hole injection layer, in the same manner as in the case of forming the hole injection layer 3 by the wet-process film formation method described above.

In the present invention, as the composition for forming an emission layer, the above-described composition for an organic electroluminescent element according to the present invention is preferably used.

Examples of the solvent include an ether-based solvent, an ester-based solvent, an aromatic hydrocarbon-based solvent, and an amide-based solvent, which are exemplified for the formation of the hole injection layer 3, and include an alkane-based solvent, a halogenated aromatic hydrocarbon-based solvent, an aliphatic alcohol-based solvent, an alicyclic alcohol-based solvent, an aliphatic ketone-based solvent, and an alicyclic ketone-based solvent. Preferred solvents are as exemplified as the first solvent, the second solvent, and other solvents of the composition for an organic electroluminescent element according to the present invention.

An amount of the solvent to be used is any as long as the effect of the present invention is not significantly impaired, but the total content of the solvent in the composition for forming an emission layer is preferably large from the viewpoint of easily executing a film formation work due to its low viscosity, and meanwhile, is preferably small from the viewpoint of easily forming a thick film. As described above, the content of the solvent is preferably 1 mass % or more, more preferably 10 mass % or more, particularly preferably 50 mass % or more, and is preferably 99.99 mass % or less, more preferably 99.9 mass % or less, particularly preferably 99 mass % or less.

As a method for removing the solvent after the wet-process film formation, heating or decompression can be used. As a heating unit used in a heating method, a clean oven and a hot plate are preferable because heat is uniformly applied to an entire film.

A heating temperature in a heating step is any as long as the effect of the present invention is not significantly impaired, but a high temperature is preferable from the viewpoint of shortening a drying time, and a low temperature is preferable from the viewpoint of reducing damage to a material. An upper limit of a heating temperature is generally 250° C. or lower, preferably 200° C. or lower, and still more preferably 150° C. or lower. A lower limit of the heating temperature is generally 30° C. or higher, preferably 50° C. or higher, and still more preferably 80° C. or higher. A temperature exceeding the above upper limit is higher than that satisfying heat resistance of a charge-transporting material or a phosphorescent material which is generally used, and may cause decomposition or crystallization, which is not preferable. When the temperature is lower than the above lower limit, a long period of time is required to remove the solvent, which is not preferable. A heating time in the heating step is appropriately determined depending on a boiling point and a vapor pressure of the solvent in the composition for forming an emission layer, heat resistance of the material, and heating conditions.

### (Formation of Emission Layer 5 by Vacuum Deposition Method)

In the case where the emission layer 5 is formed by the vacuum deposition method, generally, one type or two or more types of constituent materials (the above-described luminescent material, charge-transporting compound, and the like) of the emission layer 5 are put into a crucible disposed in a vacuum container (in a case where two or more types of materials are used, generally each type thereof is put into a separate crucible), the inside of the vacuum container is evacuated to about 10-+Pa by a vacuum pump, and then the crucible is heated (in the case where two or more types of materials are used, generally each crucible is heated) to evaporate the material while controlling an evaporation amount of the material in the crucible (in the case where two or more types of materials are used, generally each type thereof is evaporated while controlling the evaporation amount independently), and thereby forming the emission layer 5 on the hole injection layer 3 or the hole transport layer 4 placed so as to face the crucible. In the case where two or more types of materials are used, a mixture of these materials can be put in a crucible, heated, and vaporized to form the emission layer 5.

A degree of vacuum during the deposition is not limited as long as the effect of the present invention is not significantly impaired, but is generally 0.1×10⁻⁶ Torr (0.13×10⁻⁴ Pa) or higher and 9.0×10⁻⁶ Torr (12.0×10⁻⁴ Pa) or lower. A rate of deposition is not limited as long as the effect of the present invention is not significantly impaired, but is generally 0.1 Å/sec or higher and 5.0 Å/sec or lower. A film formation temperature during the deposition is not limited as long as the effect of the present invention is not significantly impaired, but is preferably 10° C. or higher and 50° C. or lower.

### [Hole Blocking Layer 6]

The hole blocking layer 6 may be provided between the emission layer 5 and an electron injection layer 8 to be described later. The hole blocking layer 6 is a layer laminated on the emission layer 5 so as to be in contact with an interface on a cathode 9 side of the emission layer 5

The hole blocking layer 6 has a function of blocking holes which are moving thereinto from the anode 2 from reaching the cathode 9 and a function of efficiently transporting electrons injected from the cathode 9 toward the emission layer 5. Examples of physical properties required of a material constituting the hole blocking layer 6 include: to have a high electron mobility and a low hole mobility; to have a large energy gap (difference between HOMO and LUMO); and to have a high excited triplet level (Tl).

Examples of the material of the hole blocking layer 6 satisfying such requirements include metal complexes such as mixed-ligand complexes, e.g., bis(2-methyl-8-quinolinolato)(phenolato)aluminum and bis(2-methyl-8-quinolinolato)(triphenylsinolato)aluminum, and dinuclear metal complexes, e.g., bis(2-methyl-8-quinolato)aluminum-μ-oxo-bis-(2-methyl-8-quinolinolato)aluminum, styryl compounds such as distyrylbiphenyl derivatives (Japanese Patent Laid-Open No. H11-242996), triazole derivatives such as 3-(4-biphenylyl)-4-phenyl-5-(4-tert-butylphenyl)-1,2,4-triazole (Japanese Patent Laid-Open No. H7-41759), and phenanthroline derivatives such as bathocuproine (Japanese Patent Laid-Open No. H10-79297). Further, the compound disclosed in WO2005-022962 which has at least one pyridine ring substituted at the 2-, 4-, and 6-sites is also preferred as the material of the hole blocking layer 6.

A method for forming the hole blocking layer 6 is not limited, and the hole blocking layer 6 can be formed in the same manner as the method for forming the emission layer 5 described above.

A thickness of the hole blocking layer 6 is any as long as the effect of the present invention is not significantly impaired, but the thickness is generally 0.3 nm or more, preferably 0.5 nm or more, and is generally 100 nm or less, preferably 50 nm or less.

### [Electron Transport Layer 7]

The electron transport layer 7 is provided between the emission layer 5 or the hole blocking layer 6 and the electron injection layer 8 for the purpose of further improving current efficiency of an element.

The electron transport layer 7 is formed of a compound capable of efficiently transporting, between the electrodes to which an electric field is applied, the electrons injected from the cathode 9 toward the emission layer 5. An electron-transporting compound to be used in the electron transport layer 7 is required to be a compound with which efficiency of electron injection from the cathode 9 or the electron injection layer 8 is rendered high and which has high electron mobility and is capable of efficiently transporting injected electrons.

Specific examples of the electron-transporting compound satisfying such requirements include metal complexes such as aluminum complexes of 8-hydroxyquinoline (Japanese Patent Laid-Open No. S59-194393), metal complexes of 10-hydroxybenzo[h]quinoline, oxadiazole derivatives, distyrylbiphenyl derivatives, silole derivatives, 3-hydroxyflavone metal complexes, 5-hydroxyflavone metal complexes, benzoxazole metal complexes, benzothiazole metal complexes, trisbenzimidazolylbenzene (U.S. Pat. No. 5,645,948), quinoxaline compounds (Japanese Patent Laid-Open No. H6-207169), phenanthroline derivatives (Japanese Patent Laid-Open No. H5-331459), 2-t-butyl-9,10-N,N′-dicyanoanthraquinone diimine, n-type hydrogenated amorphous silicon carbide, n-type zinc sulfide, and n-type zinc selenide.

A thickness of the electron transport layer 7 is generally 1 nm or more, preferably 5 nm or more, and meanwhile, is generally 300 nm or less, preferably 100 nm or less.

The electron transport layer 7 is formed by being laminated on the emission layer 5 or the hole blocking layer 6 by the wet-process film formation method or the vacuum deposition method in the same manner as for the emission layer 5. In general, the vacuum deposition method is used.

### [Electron Injection Layer 8]

The electron injection layer 8 has a function of efficiently injecting electrons injected from the cathode 9 into the electron transport layer 7 or the emission layer 5.

In order to efficiently execute the electron injection, a metal having a low work function is preferred as a material for forming the electron injection layer 8. Examples thereof include alkali metals such as sodium and cesium, and alkaline earth metals such as barium and calcium.

A thickness of the electron injection layer 8 is preferably 0.1 nm to 5 nm.

To interpose an ultrathin insulating film (about 0.1 nm to 5 nm in thickness) of LiF, MgF₂, Li₂O, Cs₂CO₃, or the like as the electron injection layer 8 into an interface between the cathode 9 and the electron transport layer 7 is also an effective method for improving efficiency of an element (Appl. Phys. Lett., Vol. 70, p. 152, 1997; Japanese Patent Laid-Open No. H10-74586; IEEE Trans. Electron. Devices, Vol. 44, p. 1245, 1997; SID 04 Digest, p. 154).

Further, to dope an organic electron transport material represented by nitrogen-containing heterocyclic compounds such as bathophenanthroline or by metal complexes such as aluminum complexes of 8-hydroxyquinoline with an alkali metal such as sodium, potassium, cesium, lithium, or rubidium (as disclosed in Japanese Patent Laid-Open No. H10-270171, JP2002-100478A, JP2002-100482A, etc.) is preferred because the doping can attain both improvement of the electron injection and transporting property and excellent film quality. In this case, the thickness is generally 5 nm or more, preferably 10 nm or more, and is generally 200 nm or less, preferably 100 nm or less.

The electron injection layer 8 is formed by being laminated on the emission layer 5 or the hole blocking layer 6 or the electron transport layer 7 thereon by the wet-process film formation method or the vacuum deposition method in the same manner as for the emission layer 5.

Details in the case of the wet-process film formation method are the same as those in the case of the emission layer 5 described above.

### [Cathode 9]

The cathode 9 has a function of injecting electrons into a layer located on the emission layer 5 side (electron injection layer 8, the emission layer 5, or the like). Although a material used for the anode 2 can be used as a material of the cathode 9, a metal having a low work function is preferably used from the viewpoint of efficient electron injection, and for example, metals such as tin, magnesium, indium, calcium, aluminum, and silver or alloys of these metals are used. Specific examples thereof include electrodes of alloys having a low work function, such as magnesium-silver alloys, magnesium-indium alloys, and aluminum-lithium alloys.

From the viewpoint of stability of the element, it is preferable to protect the cathode 9 made of a metal having a low work function by laminating a metal layer having a high work function and being stable to the atmosphere on the cathode 9. Examples of the metal to be laminated include metals such as aluminum, silver, copper, nickel, chromium, gold, and platinum.

A thickness of the cathode is generally the same as that of the anode 2.

### [Other Constituent Layers]

Descriptions were given above mainly on elements of a layer configuration shown in the FIGURE, but the organic electroluminescent element according to the present invention may have any layer, besides the layers described above, between the anode 2 and the emission layer 5 and between the cathode 9 and the emission layer 5, or any layer other than the emission layer 5 may be omitted, as long as performance of the elements is not impaired thereby.

It is also effective to provide an electron blocking layer between the hole transport layer 4 and the emission layer 5 for the same purpose as that of the hole blocking layer 6. The electron blocking layer not only has a function of blocking electrons which are moving thereinto from the emission layer 5 from reaching the hole transport layer 4 and thereby increasing probability of recombination with holes within the emission layer 5 and confining the resultant excitons in the emission layer 5, but also has the function of efficiently transporting holes injected from the hole transport layer 4 toward the emission layer 5.

Examples of properties required of the electron blocking layer include: to have high hole transportability; to have a large energy gap (difference between HOMO and LUMO); and to have a high excited triplet level (Tl). In the case where the emission layer 5 is formed by the wet-process film formation method, the electron blocking layer is also preferably formed by a wet-process film formation method because element production is facilitated.

Consequently, it is preferable that the electron blocking layer also has suitability for wet-process film formation, and examples of materials usable as such an electron blocking layer include copolymers of dioctylfluorene with triphenylamine which are represented by F8-TFB (WO2004-084260).

Incidentally, a structure reverse to that shown in the FIGURE is also possible, that is, the cathode 9, the electron injection layer 8, the electron transport layer 7, the hole blocking layer 6, the emission layer 5, the hole transport layer 4, the hole injection layer 3, and the anode 2 may be laminated on the substrate 1 in this order, and the organic electroluminescent element according to the present invention may also be provided between two substrates, at least one of which is highly transparent.

Further, it is also possible to configure a structure in which a plurality of stages each having the layer configuration shown in the FIGURE are stacked (structure obtained by stacking a plurality of luminescent units). In this case, for example, when V₂O₅ or the like is used as a charge generation layer in place of an interface layer (two layers in a case where the anode is ITO and the cathode is Al) between stages (between luminescent units), a barrier between the stages is reduced, which is more preferable from the viewpoint of emission efficiency and driving voltage.

The present invention can be applied to any of a single organic electroluminescent element, organic electroluminescent elements configured in an array arrangement, organic electroluminescent elements configured such that the anodes and the cathodes are disposed in an X-Y matrix arrangement.

### [Display Device and Illuminator]

The display device and the illuminator according to the present invention use the organic electroluminescent element according to the present invention as described above. Types and structures of the display device and the illuminator according to the present embodiment are not particularly limited, and can be assembled using the organic electroluminescent element according to the present invention in accordance with ordinary methods.

For example, the display device and the illuminator according to the present invention can be formed by a method such as that described in “Organic EL Display” (Ohmsha, Ltd., published on Aug. 20, 2004, written by TOKITO Shizuo, ADACHI Chihaya, and MURATA Hideyuki).

### EXAMPLES

Hereinafter, the present invention will be described in more detail with reference to examples. However, the present invention is not limited to the following examples, and the present invention can be implemented with any changes without departing from the gist thereof.

### Example 1

A compound 1 (charge-transporting material) having a structure represented by the following formula (7) and a compound 2 (luminescent material) having a structure represented by the following formula (8) were mixed at a mass ratio of 90:10 to obtain an emission layer material 1. The emission layer material 1 was added to 1,1-diphenylpentane (first solvent) in an amount of 4.0 mass %, an ambient atmosphere was substituted with nitrogen, and then the mixture was dissolved by heating at 68° C. for 1 hour to prepare emission layer stock solution ink 1.

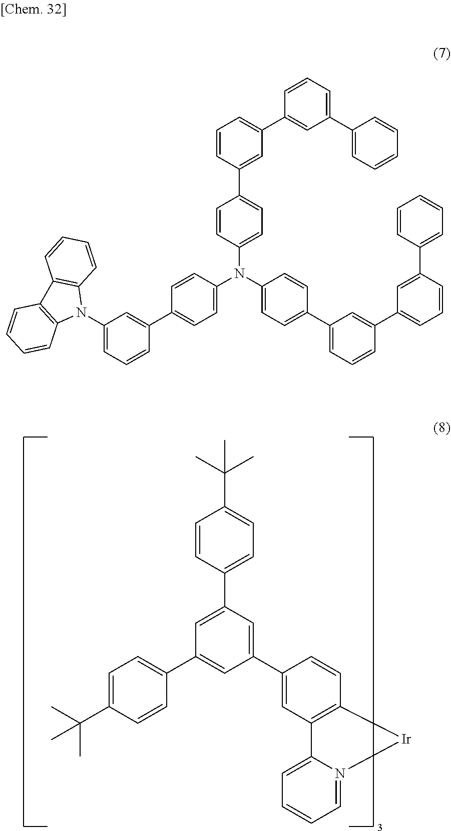

With respect to the emission layer stock solution ink 1 returned to room temperature, anisole (second solvent) and 1,1-diphenylpentane were used to dilute the emission layer stock solution ink 1 such that a mass ratio of anisole to 1,1-diphenylpentane was 50:50 and a concentration of the emission layer material 1 was 2.0 mass %, thereby preparing emission layer ink 1. With respect to the emission layer ink 1, 2,6-di-tert-butylphenol (BHB) was further added thereto such that the concentration was 500 mass ppm, thereby preparing emission layer ink 1-1 (composition for forming emission layer).

When the emission layer ink 1-1 was stored in a vial bottle in the air atmosphere for about one month, while initial surface tension thereof was 34.1 mN/m, surface tension after storage was 34.3 mN/m, with a variation width of less than 0.5 mN/m.

### Example 2

With respect to the above emission layer stock solution ink 1, 3-phenoxytoluene (second solvent) and 1,1-diphenylpentane were used to dilute the emission layer stock solution ink 1 such that a mass ratio of 3-phenoxytoluene to 1,1-diphenylpentane was 50:50 and the concentration of the emission layer material 1 was 2.0 mass %, thereby preparing emission layer ink 2. With respect to the emission layer ink 2, 2,6-di-tert-butylphenol (BHB) was further added thereto such that the concentration was 500 mass ppm, thereby preparing emission layer ink 2-1 (composition for forming emission layer).

When the emission layer ink 2-1 was stored in a vial bottle in the air atmosphere for about one month, while initial surface tension was 34.8 mN/m, surface tension after storage was 34.8 mN/m, with a variation width of less than 0.5 mN/m.

### Comparative Example 1

With respect to the above emission layer stock solution ink 1, only 1,1-diphenylpentane (first solvent) was used to dilute the emission layer stock solution ink 1 such that the concentration of the emission layer material 1 was 2.0 mass %, thereby preparing emission layer ink 3. With respect to the emission layer ink 3, 2,6-di-tert-butylphenol (BHB) was further added thereto such that the concentration was 500 mass ppm, thereby preparing emission layer ink 3-1 (composition for forming emission layer).

When the emission layer ink 3-1 was stored in a vial bottle in the air atmosphere for about one month, while initial surface tension thereof was 35.4 mN/m, surface tension after storage was 34.8 mN/m, with a variation width of 0.5 mN/m or more.

### Comparative Example 2

With respect to the above emission layer stock solution ink 1, phenylcyclohexane (second solvent for comparison) and 1,1-diphenylpentane (first solvent) were used to dilute the emission layer stock solution ink 1 such that a mass ratio of phenylcyclohexane to 1,1-diphenylpentane was 50:50 and the concentration of the emission layer material 1 was 2.0 mass %, thereby preparing emission layer ink 4. With respect to the emission layer ink 4, 2,6-di-tert-butylphenol (BHB) was further added thereto such that the concentration was 500 mass ppm, thereby preparing emission layer ink 4-1 (composition for forming emission layer).

When the emission layer ink 4-1 was stored in a vial bottle in the air atmosphere for about one month, while initial surface tension thereof was 35.4 mN/m, surface tension after storage was 34.9 mN/m, with a variation width exceeding 0.5 mN/m.

### Examples 3 to 10 and Comparative Example 3

Compositions for forming an emission layer of Examples 3 to 10 and Comparative Example 3 were each obtained in the same manner as in Example 1 except that solvents shown in Table 1 were used as the first solvent, the second solvent, and the second solvent for comparison. Surface tension of each of the obtained compositions for forming an emission layer was evaluated in the same manner as in Example 1.

### Comparative Examples 4 and 5

The surface tension was evaluated in the same manner as in Example 1 except that the solvents shown in Table 1 were used as the first solvent, the second solvent, and a first solvent for comparison, the second solvent was used to prepare emission layer stock solution ink, and the first solvent was used to obtain a composition for forming an emission layer.

### Comparative Example 6

Cumene (first solvent for comparison) and propyl benzoate (second solvent) were used to prepare emission layer ink such that a mass ratio of cumene to propyl benzoate was 50:50 and the concentration of the emission layer material 1 described in Example 1 was 2.0 mass %. With respect to the emission layer ink, 2,6-di-tert-butylphenol (BHB) was further added thereto such that the concentration was 500 mass ppm, thereby preparing a composition for forming an emission layer. The surface tension was evaluated in the same manner as in Example 1 except that the composition for forming an emission layer was prepared.

Table 1 summarizes results of studies on these examples and comparative examples.

TABLE 1

| | | | | Surface tension (mN/m) | | |
|---|---|---|---|---|---|---|
| | Phenol | | | | After storage for | Variation |
| | derivative | First solvent | Second solvent | Initial | one month | range |
| Example 1 | BHB | 1,1-diphenylpentane | Anisole | 34.1 | 34.3 | 0.2 |
| Example 2 | BHB | 1,1-diphenylpentane | 3-phenoxytoluene | 34.8 | 34.8 | 0.0 |
| Example 3 | BHB | 2,7-diisopropylnaphthalene | Anisole | 33.7 | 33.7 | 0.0 |
| Example 4 | BHB | 2,7-diisopropylnaphthalene | 3-phenoxytoluene | 34.0 | 34.4 | 0.4 |
| Example 5 | BHB | 2,7-diisopropylnaphthalene | Butyl benzoate | 33.0 | 32.9 | 0.1 |
| Example 6 | BHB | 1,1-diphenylhexane | Benzyl benzoate | 35.3 | 35.4 | 0.1 |
| Example 7 | BHB | 1,1-diphenylhexane | Propyl benzoate | 33.7 | 34.0 | 0.3 |
| Example 8 | BHB | 1,1-diphenylhexane | 2-ethylhexyl benzoate | 33.6 | 34.0 | 0.4 |
| Example 9 | BHB | 2-isopropylnaphthalene | Propyl benzoate | 34.0 | 34.3 | 0.3 |
| Example 10 | BHB | 2-isopropylnaphthalene | Benzyl benzoate | 35.3 | 35.5 | 0.2 |
| Comparative | BHB | 1,1-diphenylpentane | — | 35.4 | 34.8 | 0.6 |
| Example 1 | | | | | | |
| Comparative | BHB | 1,1-diphenylpentane | Phenylcyclohexane | 35.4 | 34.9 | 0.5 |
| Example 2 | | | | | | |
| Comparative | BHB | 2,7-diisopropylnaphthalene | Phenylcyclohexane | 35.0 | 33.8 | 1.2 |
| Example 3 | | | | | | |
| Comparative | BHB | Phenylcyclohexane | Anisole | 34.9 | 35.4 | 0.5 |
| Example 4 | | | | | | |
| Comparative | BHB | Tetralin | 3-phenoxytoluene | 35.4 | 36.2 | 0.8 |
| Example 5 | | | | | | |
| Comparative | BHB | Cumene | Propyl benzoate | 31.7 | 32.2 | 0.5 |
| Example 6 | | | | | | |

As shown in Table 1, by using alkylated naphthalene or diphenyl alkane as the first solvent and at least one of an aromatic ether or an aromatic ester as the second solvent, the change in surface tension of the ink after long-term storage was reduced, and a composition for an organic electroluminescent element having high stability could be obtained.

Although various embodiments have been described above with reference to the drawing, it goes without saying that the present invention is not limited to such examples. It is clear that those skilled in the art can come up with various changes or modifications within the scope of the claims, and it is understood that these also naturally fall within the technical scope of the present invention. In addition, each of the constituent elements in the above embodiments may be freely combined without departing from the spirit of the present invention.

The present application is based on Japanese patent application No. 2022-019088 filed on Feb. 9, 2022 and Japanese patent application No. 2022-019089 filed on Feb. 9, 2022, the content of which is incorporated by reference into the present application.

### INDUSTRIAL APPLICABILITY

According to the present invention, it is possible to provide a composition for an organic electroluminescent element, which is used for forming an emission layer in an organic electroluminescent element by wet-process film formation, and which has favorable stability of liquid physical properties, in particular, favorable surface tension stability of ink. According to the present invention, it is also possible to provide a method for producing an organic electroluminescent element using the composition for an organic electroluminescent element, an organic electroluminescent element obtained by the production method, and a display device and an illuminator including the organic electroluminescent element.

### REFERENCE SIGNS LIST

1: substrate
2: anode
3: hole injection layer
4: hole transport layer
5: emission layer
6: hole blocking layer
7: electron transport layer
8: electron injection layer
9: cathode
10: organic electroluminescent element

1. A composition for an organic electroluminescent element, comprising:
a functional material,
a compound represented by the following formula (1),
alkylated naphthalene or diphenyl alkane as a first solvent, and
at least one of an aromatic ether and an aromatic ester as a second solvent, 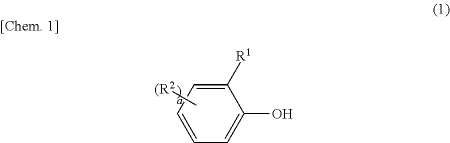
[in the above formula,
a is an integer of 0 to 4;
R¹ and R² each independently represent an alkyl group having 1 to 12 carbons or an alkoxy group having 1 to 12 carbons; and
in a case where a plurality of R² are present, the plurality of R² may be the same as or different from each other.]

2. The composition for an organic electroluminescent element according to claim 1, wherein the diphenyl alkane is represented by the following formula (4B): 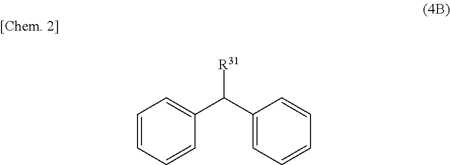
[In the above formula, R³¹ represents a hydrogen atom or an alkyl group.]

3. The composition for an organic electroluminescent element according to claim 1, wherein
the compound represented by the formula (1) is a compound represented by the following formula (1-1): 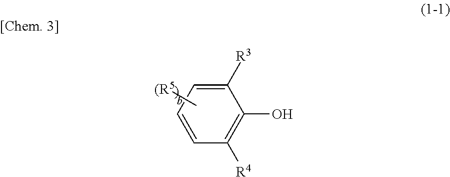
[in the above formula,
b is an integer of 0 to 3;
R³, R⁴, and R⁵ each independently represent an alkyl group having 1 to 12 carbons or an alkoxy group having 1 to 12 carbons; and
in a case where a plurality of R⁵ are present, the plurality of R⁵ may be the same as or different from each other.]

4. The composition for an organic electroluminescent element according to claim 3, wherein
the compound represented by the formula (1-1) is a compound represented by the following formula (1-2): 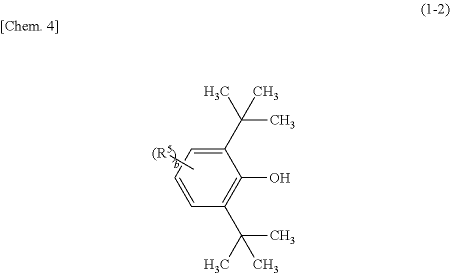
[in the above formula, b and R⁵ have the same meaning as b and R⁵ in the formula (1-1).]

5. The composition for an organic electroluminescent element according to claim 1, wherein
the functional material includes an iridium complex.

6. The composition for an organic electroluminescent element according to claim 5, wherein
the iridium complex is represented by the following formula (2): 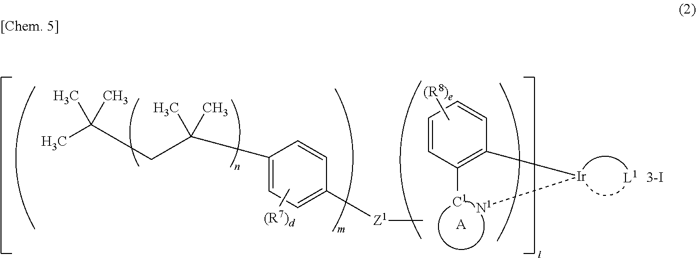
[in the above formula,
R⁷ and R⁸ are each independently any of an alkyl group having 1 to 20 carbon atoms, a (hetero) aralkyl group having 7 to 40 carbon atoms, an alkoxy group having 1 to 20 carbon atoms, a (hetero) aryloxy group having 3 to 20 carbon atoms, an alkylsilyl group having 1 to 20 carbon atoms, an arylsilyl group having 6 to 20 carbon atoms, an alkylcarbonyl group having 2 to 20 carbon atoms, an arylcarbonyl group having 7 to 20 carbon atoms, an alkylamino group having 1 to 20 carbon atoms, an arylamino group having 6 to 20 carbon atoms, and a (hetero) aryl group having 3 to 30 carbon atoms, or a combination thereof;
these groups may further have substituents, and examples of the substituent include any of a fluorine atom, a chlorine atom, a bromine atom, an alkyl group having 1 to 20 carbon atoms, a (hetero) aralkyl group having 7 to 40 carbon atoms, an alkoxy group having 1 to 20 carbon atoms, a (hetero) aryloxy group having 3 to 20 carbon atoms, an alkylsilyl group having 1 to 20 carbon atoms, an arylsilyl group having 6 to 20 carbon atoms, an alkylcarbonyl group having 2 to 20 carbon atoms, an arylcarbonyl group having 7 to 20 carbon atoms, an alkylamino group having 2 to 20 carbon atoms, an arylamino group having 6 to 20 carbon atoms, and a (hetero) aryl group having 3 to 20 carbon atoms, or a combination thereof;
in a case where a plurality of R⁷ and R⁸ are present, the plurality of R⁷ and R⁸ may be the same as or different from each other; in addition, adjacent R⁷ or R⁸ bonded to a benzene ring may be bonded to each other to form a ring that is condensed to the benzene ring;
d is an integer of 0 to 4, and e is an integer of 0 to 3;
m is an integer of 1 to 20;
n is an integer of 0 to 2;
a ring A is any of a pyridine ring, a pyrazine ring, a pyrimidine ring, an imidazole ring, an oxazole ring, a thiazole ring, a quinoline ring, an isoquinoline ring, a quinazoline ring, a quinoxaline ring, an azatriphenylene ring, and a carboline ring;
the ring A may have a substituent, and the substituent is any of a fluorine atom, a chlorine atom, a bromine atom, an alkyl group having 1 to 20 carbon atoms, a (hetero) aralkyl group having 7 to 40 carbon atoms, an alkoxy group having 1 to 20 carbon atoms, a (hetero) aryloxy group having 3 to 20 carbon atoms, an alkylsilyl group having 1 to 20 carbon atoms, an arylsilyl group having 6 to 20 carbon atoms, an alkylcarbonyl group having 2 to 20 carbon atoms, an arylcarbonyl group having 7 to 20 carbon atoms, an alkylamino group having 2 to 20 carbon atoms, an arylamino group having 6 to 20 carbon atoms, and a (hetero) aryl group having 3 to 20 carbon atoms, or a combination thereof; in addition, adjacent substituents bonded to the ring A may be bonded to each other to form a ring that is condensed to the ring A;
Z¹ represents a direct bond or an (m+1)-valent aromatic linking group;
L¹ represents an auxiliary ligand, and l is an integer of 1 to 3; and in a case where a plurality of auxiliary ligands are present, the auxiliary ligands may be different from each other or the same.]

7. The composition for an organic electroluminescent element according to claim 1, wherein
the functional material includes a polymer compound having a repeating unit containing a structure represented by the following formula (3): 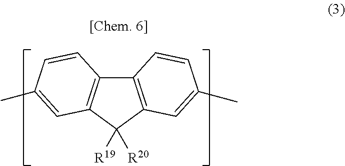
[in the formula (3), R¹⁹ and R²⁰ are each independently any of an alkyl group having 1 to 20 carbon atoms, a (hetero) aralkyl group having 7 to 40 carbon atoms, an alkoxy group having 1 to 20 carbon atoms, a (hetero) aryloxy group having 3 to 20 carbon atoms, an alkylsilyl group having 1 to 20 carbon atoms, an arylsilyl group having 6 to 20 carbon atoms, an alkylcarbonyl group having 2 to 20 carbon atoms, an arylcarbonyl group having 7 to 20 carbon atoms, an alkylamino group having 1 to 20 carbon atoms, an arylamino group having 6 to 20 carbon atoms, and a (hetero) aryl group having 3 to 30 carbon atoms, or a combination thereof; and these groups may further have substituents.]

8. The composition for an organic electroluminescent element according to claim 7, wherein
the polymer compound further has a repeating unit represented by the following formula (3-1): 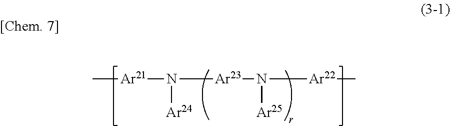
[In the formula (3-1), Ar²¹ to Ar²³ each independently represent a divalent (hetero) arylene group having 3 to 30 carbon atoms which may have a substituent;
Ar²⁴ and Ar²⁵ each independently represent a (hetero) aryl group having 3 to 30 carbon atoms which may have a substituent; and
r represents an integer of 0 to 2.]

9. The composition for an organic electroluminescent element according to claim 1, wherein
the second solvent is an aromatic ether.

10. The composition for an organic electroluminescent element according to claim 1, wherein
the second solvent is an aromatic ester.

11. A method for producing an organic electroluminescent element, comprising:
a step of forming an emission layer by a wet-process film formation method using the composition for an organic electroluminescent element according to claim 1.

12. An organic electroluminescent element comprising:
an emission layer formed using the composition for an organic electroluminescent element according to claim 1.

13. A display device comprising:
the organic electroluminescent element according to claim 12.

14. An illuminator comprising:
the organic electroluminescent element according to claim 12.
